(19) United States
(12) Patent Application Publication
(10) Pub. No.: US 2026/0100693 A1
(43) Pub. Date: Apr. 9, 2026

(54) ACOUSTIC WAVE DEVICE AND ACOUSTIC WAVE FILTER DEVICE

(71) Applicant: Murata Manufacturing Co., Ltd., Nagaokakyo-shi (JP)

(72) Inventors: Yuta ISHII, Nagaokakyo-shi (JP); Katsuya DAIMON, Nagaokakyo-shi (JP); Akihiro IYAMA, Nagaokakyo-shi (JP)

(21) Appl. No.: 19/414,735

(22) Filed: Dec. 10, 2025

Related U.S. Application Data
(63) Continuation of application No. PCT/JP2024/021583, filed on Jun. 13, 2024.

(30) Foreign Application Priority Data
Jun. 13, 2023 (JP) 2023-097236

(51) Int. Cl. H03H 9/56; H03H 9/13

(52) U.S. Cl. CPC H03H 9/568; H03H 9/133

(57) ABSTRACT

An acoustic wave device includes a piezoelectric layer including first and second main surfaces, an IDT electrode on one of the first and second main surfaces, and including electrode fingers, a support facing the second main surface, and including an acoustic reflection portion at a portion closer to the second main surface of the piezoelectric layer, and a load film extending over a region that overlaps, when viewed in plan in the first direction, at least electrode fingers from a fourth one of the electrode fingers from a first outer end in an arrangement direction to a fourth one of the electrode fingers from a second outer end in the arrangement direction. d/p is less than or equal to about 0.5 where d denotes a thickness of the piezoelectric layer, and p denotes a center-to-center distance between adjacent two of the electrode fingers.

### CROSS REFERENCE TO RELATED APPLICATIONS

This application claims the benefit of priority to Japanese Patent Application No. 2023-097236 filed on Jun. 13, 2023 and is a Continuation Application of PCT Application No. PCT/JP2024/021583 filed on Jun. 13, 2024. The entire contents of each application are hereby incorporated herein by reference.

### BACKGROUND OF THE INVENTION

### 1. Field of the Invention

The present invention relates to acoustic wave devices and acoustic wave filter devices.

### 2. Description of the Related Art

Japanese Unexamined Patent Application Publication No. 2022-524136 and U.S. Pat. No. 11,349,450 describe acoustic wave devices.

The acoustic wave devices described in Japanese Unexamined Patent Application Publication No. 2022-524136 and U.S. Pat. No. 11,349,450 may cause leakage of acoustic waves in an arrangement direction of electrode fingers.

### SUMMARY OF THE INVENTION

Example embodiments of the present invention provide acoustic wave devices and acoustic wave filter devices each able to reduce or prevent leakage of acoustic waves.

An acoustic wave device according to an example embodiment of the present invention includes a piezoelectric layer including a first main surface and a second main surface opposite to the first main surface in a first direction, an IDT electrode on at least one of the first main surface or the second main surface of the piezoelectric layer, and including a plurality of electrode fingers arranged in an arrangement direction, a support facing the second main surface of the piezoelectric layer, and including an acoustic reflection portion at a portion closer to the second main surface of the piezoelectric layer, and a load film extending over a region that overlaps, when viewed in plan in the first direction, from at least a fourth one of the plurality of electrode fingers from a first outer end in the arrangement direction to a fourth one of the plurality of electrode fingers from a second outer end in the arrangement direction, wherein, of the plurality of electrode fingers, the load film is not provided over at least a portion of a region that overlaps, in a plan view, a first electrode finger located outermost in the arrangement direction of the plurality of electrode fingers, and d/p is less than or equal to about 0.5, where d denotes a thickness of the piezoelectric layer, and p denotes a center-to-center distance between adjacent two of the electrode fingers among the plurality of electrode fingers.

An acoustic wave filter device according to an example embodiment of the present invention includes at least one resonator including an acoustic wave device according to an example of the present invention.

Acoustic wave devices and acoustic wave filter devices according to example embodiments of the present invention each reduce or prevent leakage of acoustic waves.

### BRIEF DESCRIPTION OF THE DRAWINGS

FIG. 1 is a plan view of an acoustic wave device according to a first example embodiment of the present invention.

FIG. 2 is a cross-sectional view taken along line II-II′ in FIG. 1.

FIG. 3 is a schematic cross-sectional view of a bulk wave in a thickness-shear primary mode that propagates through a piezoelectric layer in the first example embodiment of the present invention.

FIG. 4 is a schematic cross-sectional view illustrating an amplitude direction of a bulk wave in a thickness-shear primary mode that propagates through a piezoelectric layer in the first example embodiment of the present invention.

FIG. 5 is a graph of an example of resonance characteristics of an acoustic wave device according to the first example embodiment of the present invention.

FIG. 6 is a graph of the relationship, in the acoustic wave device according to the first example embodiment, between d/2p and a band width ratio defining and functioning as a resonator where a center-to-center distance between adjacent electrodes or a mean distance of the center-to-center distance is denoted by p, and a mean thickness of a piezoelectric layer is denoted by d.

FIG. 7 is a plan view of an example of the acoustic wave device according to the first example embodiment including an electrode pair.

FIG. 8 is a reference graph of an example of resonance characteristics of the acoustic wave device according to the first example embodiment of the present invention.

FIG. 9 is a graph of a relationship, in the acoustic wave device according to the first example embodiment, between a band width ratio in a structure including a large number of acoustic wave resonators and a phase rotation amount of the spurious impedance, normalized to about 180 degrees as the level of a spurious emission.

FIG. 10 is a graph of the relationship between d/2p, a metallization ratio MR, and a band width ratio.

FIG. 11 is a graph of a map of the band width ratio with respect to Euler angles (0°, θ, ψ) of LiNbO₃ when d/p is infinitely approximated to zero.

FIG. 12 is an enlarged cross-sectional view of a region A in FIG. 2.

FIG. 13 is a graph of an example of admittance characteristics of the acoustic wave device according to the first example embodiment of the present invention.

FIG. 14 is a graph of an example of admittance characteristics of an acoustic wave device according to a first modified example of the first example embodiment of the present invention.

FIG. 15 is a graph of an example of admittance characteristics of an acoustic wave device according to a second modified example of the first example embodiment of the present invention.

FIG. 16 is a cross-sectional view of an acoustic wave device according to a second example embodiment of the present invention.

FIG. 17 is a graph of an example of admittance characteristics of the acoustic wave device according to the second example embodiment of the present invention.

FIG. 18 is a cross-sectional view of an acoustic wave device according to a third example embodiment of the present invention.

FIG. 19 is a graph of an example of admittance characteristics of the acoustic wave device according to the third example embodiment of the present invention.

FIG. 20 is a cross-sectional view of an acoustic wave device according to a fourth example embodiment of the present invention.

FIG. 21 is a graph of an example of admittance characteristics of an acoustic wave device according to the fourth example embodiment of the present invention.

FIG. 22 is a cross-sectional view of an acoustic wave device according to a fifth example embodiment of the present invention.

FIG. 23 is an enlarged cross-sectional view of a region A1 in FIG. 22.

FIG. 24 is a graph of distribution of a vibration mode of the acoustic wave device according to the fifth example embodiment of the present invention.

FIG. 25 is a graph of distribution of a vibration mode of an acoustic wave device according to a comparative example.

FIG. 26 is a cross-sectional view of an acoustic wave device according to a sixth example embodiment of the present invention.

FIG. 27 is a cross-sectional view of an acoustic wave device according to a seventh example embodiment of the present invention.

FIG. 28 is a cross-sectional view of an acoustic wave device according to an eighth example embodiment of the present invention.

FIG. 29 is a cross-sectional view of an acoustic wave device according to a ninth example embodiment of the present invention.

FIG. 30 is a cross-sectional view of an acoustic wave device according to a tenth example embodiment of the present invention.

FIG. 31 is a cross-sectional view of an acoustic wave device according to an eleventh example embodiment of the present invention.

FIG. 32 is a cross-sectional view of an acoustic wave device according to a twelfth example embodiment of the present invention.

FIG. 33 is a cross-sectional view of an acoustic wave device according to a third modified example of the twelfth example embodiment of the present invention.

FIG. 34 is a circuit diagram of an acoustic wave filter device according to a thirteenth example embodiment of the present invention.

FIG. 35 is a cross-sectional view of an acoustic wave device according to a fourteenth example embodiment of the present invention.

FIG. 36 is a cross-sectional view of an acoustic wave device according to a fifteenth example embodiment of the present invention.

FIG. 37 is a graph of an example of admittance characteristics of an acoustic wave device according to a sixteenth example embodiment of the present invention.

FIG. 38 is a graph of an example of an impedance phase in a higher mode.

### DETAILED DESCRIPTION OF THE EXAMPLE EMBODIMENTS

Hereinbelow, example embodiments of the present disclosure will be described in detail with reference to the drawings. The present invention is not limited to these example embodiments. Each example embodiment described herein is merely illustrative, and partial replacement or combinations of configurations among different example embodiments are possible as modified examples. In the second and subsequent example embodiments, description of matters common to the first example embodiment are omitted, and only the differences are described. In particular, the same or similar functions and advantageous effects resulting from the same or similar configurations are not repeatedly referred to in each example embodiment.

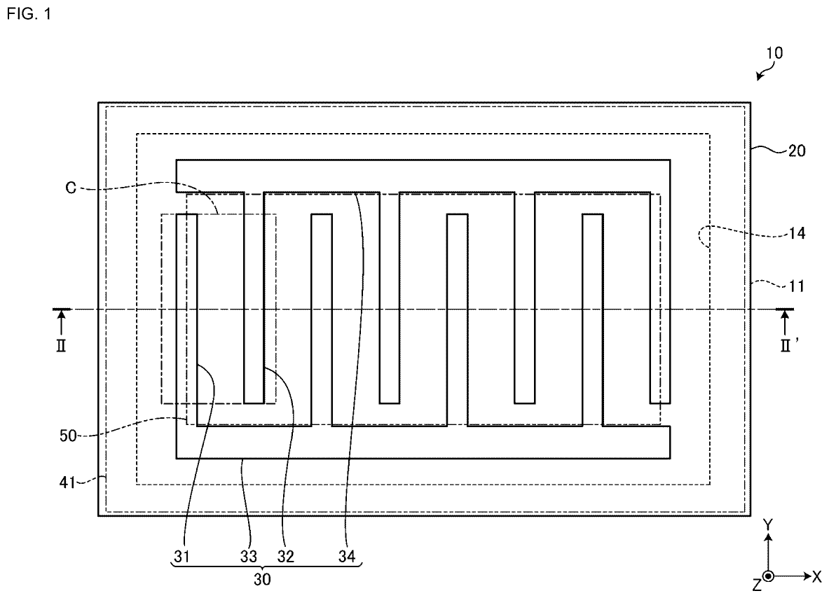

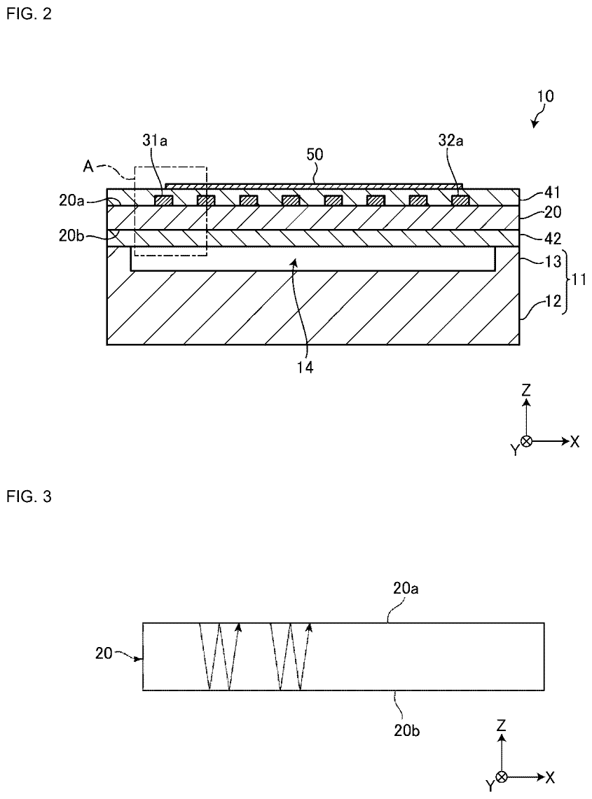

FIG. 1 is a plan view of an acoustic wave device according to a first example embodiment of the present invention. FIG. 2 is a cross-sectional view taken along line II-II′ in FIG. 1. In FIG. 1, a first protection film 41 and a load film 50 are drawn by two-dot chain lines.

As illustrated in FIG. 1 and FIG. 2, an acoustic wave device 10 according to the first example embodiment includes a piezoelectric layer 20, an interdigital transducer (IDT) electrode 30, a support substrate 11, a first protection film 41, a second protection film 42, and a load film 50. As illustrated in FIG. 2, in the acoustic wave device 10, the second protection film 42, the piezoelectric layer 20, the IDT electrode 30, the first protection film 41, and the load film 50 are laminated in this order on the support substrate 11.

The piezoelectric layer 20 is a flat board including a first main surface 20a and a second main surface 20b opposite to the first main surface 20a. The piezoelectric layer 20 includes, for example, lithium niobate (LiNbO₃). Alternatively, the piezoelectric layer 20 may include, for example, lithium tantalate (LiTaO₃). In the first example embodiment, the cut-angle of LiNbO₃ or LiTaO₃ is a Z-cut. The cut-angle of LiNbO₃ or LiTaO₃ may be a rotated Y-cut or X-cut. Preferably, for example, the propagation orientation is Y propagation and X propagation within about ±30°. Preferably, for example, the piezoelectric layer 20 includes lithium niobate (LiNbO₃) or lithium tantalate (LiTaO₃), and has a cut-angle of a rotated Y-cut of about 120°±10° or about 90°±10°. Here, 120°±10° includes the range of greater than or equal to 120°−10° and less than or equal to 120°+10°, and 90°±10° includes the range of greater than or equal to 90°−10° and less than or equal to 90°+10°.

Although not particularly limited, the thickness of the piezoelectric layer 20 is preferably greater than or equal to 50 nm and less than or equal to 1000 nm for effective excitation in a thickness-shear primary mode. The film thickness of the piezoelectric layer 20 according to the first example embodiment is, for example, about 180 nm.

The interdigital transducer (IDT) electrode 30 is disposed at the first main surface 20a of the piezoelectric layer 20. As illustrated in FIG. 1, the IDT electrode 30 includes electrode fingers 31 and 32 and busbar electrodes 33 and 34. The multiple electrode fingers 31 extend in a Y direction, and include first ends in the extension direction connected to the busbar electrode 33. The multiple electrode fingers 32 extend in the Y direction, and include second ends in the extension direction connected to the busbar electrode 34. The multiple electrode fingers 31 and the multiple electrode fingers 32 are alternately arranged in an X direction at intervals. The busbar electrode 33 and the busbar electrode 34 extend in the X direction, and are spaced apart from each other in the Y direction. The multiple electrode fingers 31 and 32 are arranged between the busbar electrode 33 and the busbar electrode 34.

In the description described below, the thickness direction of the piezoelectric layer 20 may be described as a Z direction, the extension direction of the electrode fingers 31 and 32 may be described as the Y direction, and the arrangement direction of the electrode fingers 31 and 32 may be described as the X direction. In the description described below, a plan view indicates an arrangement relation viewed in a direction perpendicular to the first main surface 20a of the piezoelectric layer 20.

Preferably, the center-to-center distance between each electrode finger 31 and the corresponding electrode finger 32 (hereafter referred to as an inter-electrode pitch) is, for example, within the range greater than or equal to about 1 μm and less than or equal to about 10 μm. The inter-electrode pitch is a distance connecting the width center of each electrode finger 31 in the direction perpendicular or substantially perpendicular to the extension direction of the electrode finger 31 and the width center of the corresponding electrode finger 32 in the direction perpendicular or substantially perpendicular to the extension direction of the electrode finger 32. The width of the electrode fingers 31 and the electrode fingers 32 (hereafter referred to as an electrode width), more specifically, the dimension of the electrode fingers 31 and the electrode fingers 32 in a direction perpendicular or substantially perpendicular to the extension direction of the electrode fingers 31 and the electrode fingers 32 is, for example, preferably within a range greater than or equal to about 150 nm and less than or equal to about 1000 nm.

When the IDT electrode 30 includes multiple electrode fingers 31 or multiple electrode fingers 32, or multiple electrode fingers 31 and multiple electrode fingers 32 (the IDT electrode 30 includes greater than or equal to 1.5 pairs in a case where one electrode finger 31 and one electrode finger 32 define an electrode pair), the inter-electrode pitch between the electrode finger 31 and the electrode finger 32 indicates the mean value of the center-to-center distance between the adjacent electrode fingers 31 and 32 in greater than or equal to 1.5 pairs of the electrode fingers 31 and 32.

In the first example embodiment, a Z-cut piezoelectric layer is provided. Thus, the direction perpendicular or substantially perpendicular to the extension direction of the electrode fingers 31 and the electrode fingers 32 is the direction perpendicular or substantially perpendicular to the polarization direction of the piezoelectric layer 20. This is not the case when a piezoelectric material with another cut-angle is used for the piezoelectric layer 20. Herein, the term “perpendicular” is not limited to strictly perpendicular, but may be applied to substantially perpendicular (when an angle formed by the direction perpendicular to the extension direction of the electrode fingers 31 and the electrode fingers 32 and the polarization direction is, for example, about 90°±10°).

The IDT electrode 30 (electrode fingers 31 and 32 and busbar electrodes 33 and 34) is made of an appropriate metal or alloy, such as Al or an AlCu alloy. In the first example embodiment, for example, the IDT electrode 30 has a structure in which an Al film is laminated on a titanium (Ti) film. Alternatively, the IDT electrode 30 may include a close contact layer other than a Ti film.

More specifically, for example, the IDT electrode 30 has an electrode structure of Ti, AlCu, Ti, and AlCu films laminated from near the piezoelectric layer 20, and the films have thicknesses of about 12 nm, about 70 nm, about 18 nm, and about 12 nm, respectively. The sum of the electrode fingers 31 and 32 of the IDT electrode 30 is, for example, 51. The inter-electrode pitch between the electrode fingers 31 and 32 is, for example, about 2.38 μm, and the electrode width of each of the electrode fingers 31 and 32 is, for example, about 0.6 μm.

An intersecting region C (excitation region) illustrated in FIG. 1 is a region where the electrode finger 31 and the electrode finger 32 overlap when viewed in the X direction. The length of the intersecting region C is a dimension of the electrode finger 31 and the electrode finger 32 in the extension direction in the intersecting region C. In the present example embodiment, the length of the intersecting region C is, for example, about 40 μm.

To drive the acoustic wave device 10, an alternating current (AC) voltage is applied across the multiple electrode fingers 31 and the multiple electrode fingers 32. More specifically, an alternating current (AC) voltage is applied across the busbar electrode 33 and the busbar electrode 34. Thus, resonance characteristics can be obtained using bulk waves in a thickness-shear primary mode excited at the piezoelectric layer 20.

In the acoustic wave device 10, for example, d/p is less than or equal to about 0.5 when the thickness of the piezoelectric layer 20 is denoted with d, and the inter-electrode pitch between multiple pairs of electrode fingers 31 and 32 is denoted with p. Thus, bulk waves in the thickness-shear primary mode are effectively excited, and the acoustic wave device 10 can obtain preferable resonance characteristics. More preferably, for example, when d/p is less than or equal to about 0.24, the acoustic wave device 10 can obtain more preferable resonance characteristics.

The acoustic wave device 10 according to the first example embodiment has the above structure, and is thus less likely to reduce a Q value regardless of when reducing the number of pairs of the electrode fingers 31 and 32 for size reduction. This is because the acoustic wave device is a resonator that does not include reflectors on both sides, and thus has a small propagation loss. The acoustic wave device does not include reflectors because the acoustic wave device uses bulk waves in a thickness-shear primary mode.

The first protection film 41 is disposed at the first main surface 20a of the piezoelectric layer 20 while covering the IDT electrode 30. The second protection film 42 is disposed at the second main surface 20b of the piezoelectric layer 20. The first protection film 41 and the second protection film 42 are made of, for example, silicon oxide (SiO₂). Instead of silicon oxide, the first protection film 41 and the second protection film 42 may be made of an appropriate insulating material such as silicon nitride or alumina, for example. A film thickness t1 of the first protection film 41 and a film thickness t2 of the second protection film 42 are, for example, about 142 nm. The film thickness t1 of the first protection film 41 is the maximum total distance from a surface of the first protection film 41 closer to the first main surface 20a to a surface of the first protection film 41 away from the first main surface 20a in the intersecting region C. The film thickness t2 of the second protection film 42 is the maximum total distance from a surface of the second protection film 42 closer to the second main surface 20b to a surface of the second protection film 42 away from the second main surface 20b in the intersecting region C. The acoustic wave device may include at least one of the first protection film 41 or the second protection film 42. For example, the acoustic wave device may include the first protection film 41 without including the second protection film 42.

The load film 50 is disposed on the first protection film 41. The load film 50 extends over a region that overlaps at least electrode fingers among the multiple electrode fingers 31 and 32, from a fourth electrode finger 31 from an outer end in an arrangement direction of the multiple electrode fingers 31 and 32 to a fourth electrode finger 32 from an outer end and away from a first electrode finger 31a. In the first example embodiment, the load film 50 extends over a region that overlaps electrode fingers among the multiple electrode fingers 31 and 32, from the electrode finger 31 located outermost (hereafter referred to as a first electrode finger 31a) in the arrangement direction of the multiple electrode fingers 31 and 32 to the electrode finger 32 located outermost (hereafter referred to as a second electrode finger 32a) away from the first electrode finger 31a.

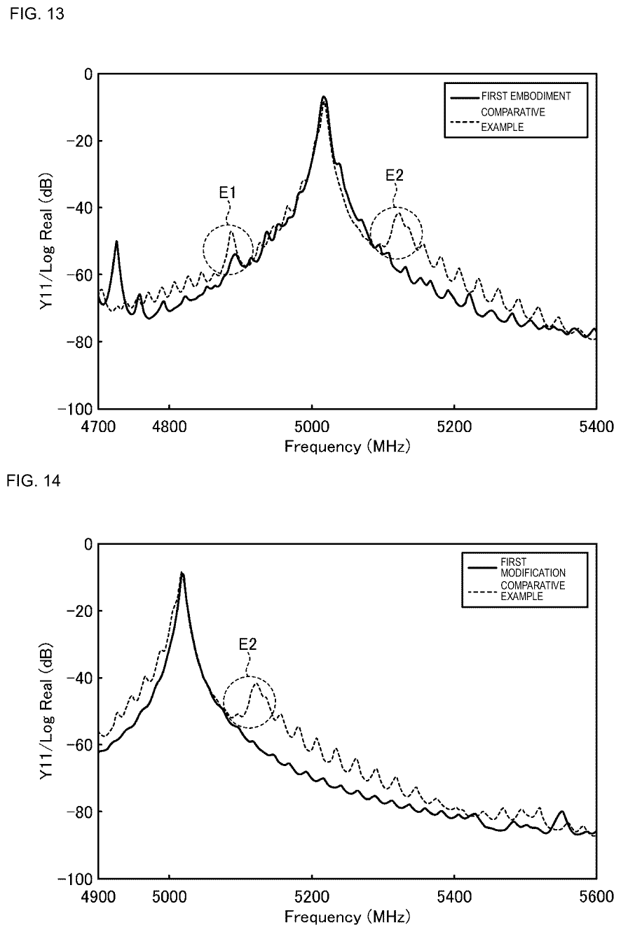

In the description below, a portion of the load film 50 extending over a region that overlaps at least electrode fingers among the multiple electrode fingers 31 and 32, from a fourth electrode finger 31 from an outer end in an arrangement direction of the multiple electrode fingers 31 and 32 to a fourth electrode finger 32 from an outer end and away from the first electrode finger 31a may be referred to as an inner load film 51. The detailed structure of the load film 50 is described later with reference to FIG. 12 and FIG. 13.

The support substrate 11 (a support) faces the second main surface 20b of the piezoelectric layer 20. The support substrate 11 includes a cavity portion 14 (a space) on the surface that faces the second main surface 20b of the piezoelectric layer 20. More specifically, the support substrate 11 includes a bottom portion 12 and a wall portion 13 in a frame shape at the upper surface of the bottom portion 12. The bottom portion 12 and the wall portion 13 define a space defining and functioning as the cavity portion 14. On the upper surface of the wall portion 13 of the support substrate 11, the piezoelectric layer 20 is laminated with the second protection film 42 interposed therebetween. As described above, the acoustic wave device 10 has a membrane structure including the cavity portion 14 (a hollow portion) located closer to the second main surface 20b of the piezoelectric layer 20. The support may include the support substrate 11 and an intermediate (insulating) layer. More specifically, the support substrate 11 may be indirectly laminated on the second main surface 20b of the piezoelectric layer 2. In this case, the support substrate 11 and the intermediate layer may have a frame shape to thus define the cavity portion 14. Alternatively, an intermediate layer may include a recessed portion to define and function as the cavity portion 14.

The cavity portion 14 is configured not to interfere with vibrations of the intersecting region C of the piezoelectric layer 20. The second protection film 42 is disposed to cover the cavity of the cavity portion 14. However, as described above, the second protection film 42 may be eliminated. In this case, the support substrate 11 may be directly laminated on the second main surface 20b of the piezoelectric layer 20. Alternatively, the second protection film 42 may be disposed over a region between the upper surface of the wall portion 13 and the second main surface 20b of the piezoelectric layer 20, without being disposed over a region overlapping the cavity portion 14.

The support substrate 11 is made of, for example, silicon (Si). The plane direction of the plane of Si closer to the piezoelectric layer 20 may be (100), (110), or (111). Preferably, for example, Si has high resistance with a resistivity greater than or equal to about 4 kΩ. The support substrate 11 may be made of an appropriate insulating material or semiconductor material. Examples of the support substrate 11 include a piezoelectric material such as aluminum oxide, lithium tantalate, lithium niobate, or crystal, a ceramic material such as alumina, magnesia, sapphire, silicon nitride, aluminum nitride, silicon carbide, zirconia, cordierite, mullite, steatite, or forsterite, a dielectric material such as diamond or glass, and a semiconductor material such as gallium nitride.

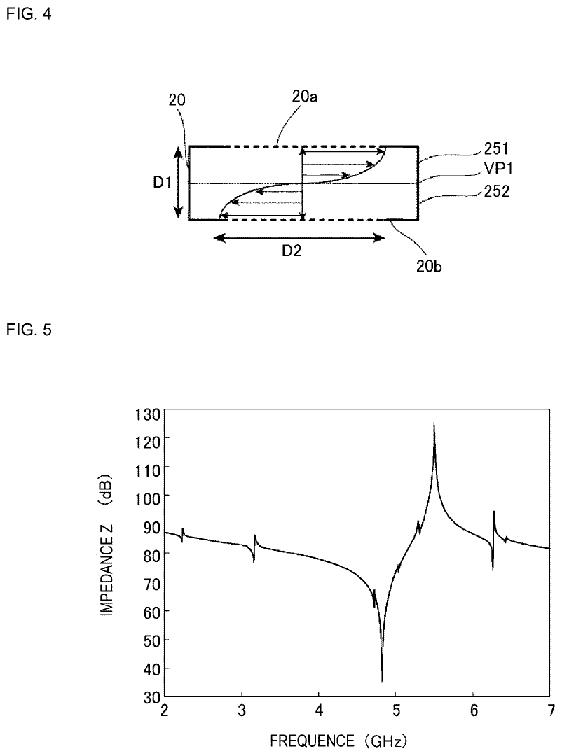

FIG. 3 is a schematic cross-sectional view illustrating a bulk wave in a thickness-shear primary mode that propagates through a piezoelectric layer in the first example embodiment. FIG. 4 is a schematic cross-sectional view illustrating an amplitude direction of a bulk wave in a thickness-shear primary mode that propagates through a piezoelectric layer in the first example embodiment.

As illustrated in FIG. 3, in the acoustic wave device 10 according to the first example embodiment, vibration displacement occurs in a thickness-shear direction. Thus, the wave substantially propagates in a direction connecting the first main surface 20a and the second main surface 20b of the piezoelectric layer 20, or specifically, in the Z direction and resonates. More specifically, the X-direction component in the wave is remarkably smaller than the Z-direction component. The resonance characteristics are obtained by propagation of the wave in the Z direction, and thus the acoustic wave device does not include any reflector. Thus, the acoustic wave device does not cause propagation loss caused by propagation to a reflector. Thus, the acoustic wave device is less likely to reduce the Q value regardless of reducing the number of pairs of the electrode fingers 31 and 32 for size reduction.

As illustrated in FIG. 4, the amplitude direction of a bulk wave in a thickness-shear primary mode for a first region 251 included in the intersecting region C (refer to FIG. 1) of the piezoelectric layer 20 is opposite to the amplitude direction of a bulk wave in a thickness-shear primary mode for a second region 252 included in the intersecting region C. FIG. 4 schematically illustrates a bulk wave when a voltage that allows the electrode fingers 32 to have a higher potential than the electrode fingers 31 is applied across the electrode fingers 31 and the electrode fingers 32. A virtual plane VP1 is a plane that is perpendicular or substantially perpendicular to the thickness direction of the piezoelectric layer 20 and that bisects the piezoelectric layer 20. The first region 251 is a region in the intersecting region C between the virtual plane VP1 and the first main surface 20a. The second region 252 is a region in the intersecting region C between the virtual plane VP1 and the second main surface 20b.

The acoustic wave device 10 includes at least one electrode pair including the electrode finger 31 and the electrode finger 32. The acoustic wave device 10 does not propagate waves in the X direction, and thus does not need to include multiple electrode pairs each including the electrode finger 31 and the electrode finger 32. More specifically, the acoustic wave device 10 only needs to include at least one electrode pair.

For example, the electrode fingers 31 are electrodes connected to a hot potential, and the electrode fingers 32 are electrodes connected to the ground potential. Alternatively, the electrode fingers 31 may be connected to the ground potential, and the electrode fingers 32 may be connected to the hot potential. In the first example embodiment, as described above, at least one electrode pair are electrodes connected to the hot potential or electrodes connected to the ground potential, and no floating electrode is included.

FIG. 5 is a graph of an example of resonance characteristics of an acoustic wave device according to the first example embodiment. The design parameters of the acoustic wave device 10 having the resonance characteristics illustrated in FIG. 5 are described as below:
Piezoelectric layer 20: LiNbO₃ with Euler angles (0°, 0°, 90°)
Thickness of piezoelectric layer 20: about 400 nm
Length of intersecting region C: about 40 μm
Number of electrode pairs including electrode fingers 31 and 32: 21 pairs
Inter-electrode pitch between electrode fingers 31 and 32: about 3 μm
Width of electrode fingers 31 and 32: about 500 nm
d/p: about 0.133
First protection film 41 and second protection film 42: silicon oxide film with thickness of about 1 μm
Support substrate 11: Si

In the first example embodiment, all of the multiple electrode pairs including the electrode finger 31 and the electrode finger 32 have an equal or substantially equal inter-electrode pitch. More specifically, the electrode fingers 31 and the electrode fingers 32 are arranged at an equal or substantially equal pitch.

As is clear from FIG. 5, although the acoustic wave device includes no reflector, the acoustic wave device has preferable resonance characteristics with a band width ratio of about 12.5%.

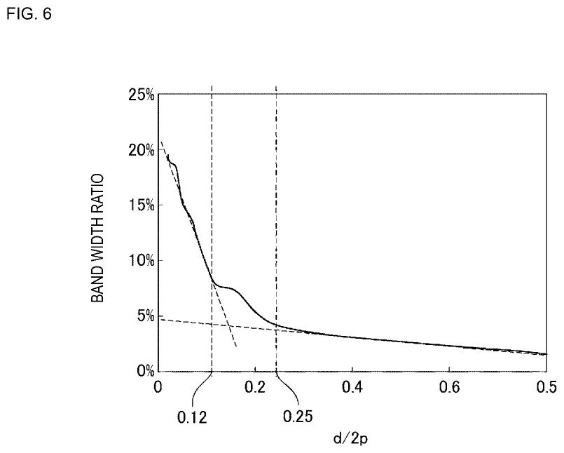

When the thickness of the piezoelectric layer 20 is denoted by d, and the inter-electrode pitch of the electrode fingers 31 and the electrode fingers 32 is denoted by p, in the first example embodiment, for example, d/p is less than or equal to about 0.5, or more preferably, less than or equal to about 0.24. This structure is described with reference to FIG. 6.

FIG. 6 is a graph of the relationship, in the acoustic wave device according to the first example embodiment, between d/2p and a band width ratio defining and functioning as a resonator when a center-to-center distance between adjacent electrodes or a mean distance of the center-to-center distance is denoted by p, and a mean thickness of a piezoelectric layer is denoted by d. In FIG. 6, multiple acoustic wave devices that were similar to the acoustic wave device having resonance characteristics illustrated in FIG. 5, with d/2p varied from that of the acoustic wave device in FIG. 5 were obtained.

As illustrated in FIG. 6, when d/2p exceeds about 0.25, more specifically, when d/p>about 0.5, the band width ratio is less than about 5% regardless of adjustment of d/p. In contrast, when d/2p≤about 0.25, more specifically, when d/p≤about 0.5, the band width ratio can be changed to be greater than or equal to about 5% with a change of d/p within the range, or more specifically, a resonator with a high coupling coefficient can be formed. When d/2p is less than or equal to about 0.12, more specifically, when d/p is less than or equal to about 0.24, the band width ratio can be increased to be greater than or equal to about 7%. In addition, when d/p is adjusted within this range, a resonator with a greater band width ratio and a higher coupling coefficient can be obtained. Thus, when d/p is changed to be less than or equal to about 0.5, a resonator with a high coupling coefficient and using bulk waves in the thickness-shear primary mode can be obtained.

When the thickness d of the piezoelectric layer 20 has variations, an average thickness may be used as the thickness.

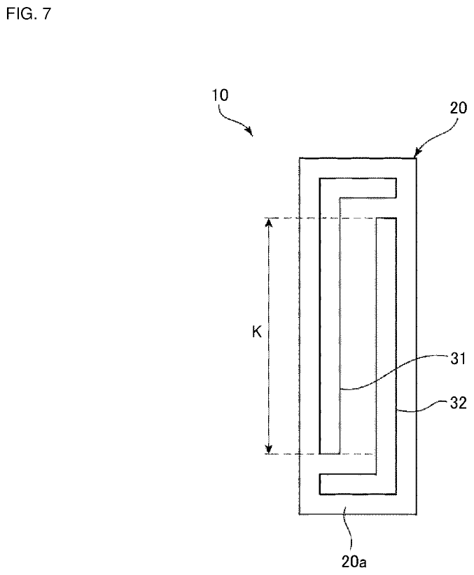

FIG. 7 is a plan view of an example of the acoustic wave device according to the first example embodiment including one electrode pair. In the acoustic wave device 10, one electrode pair including the electrode finger 31 and the electrode finger 32 is disposed on the first main surface 20a of the piezoelectric layer 20. K in FIG. 7 indicates an intersecting width. As described above, the acoustic wave device 10 according to example embodiments of the present invention may include one electrode pair. Also in this case, when d/p is less than or equal to about 0.5, the acoustic wave device 10 can effectively excite bulk waves in the thickness-shear primary mode.

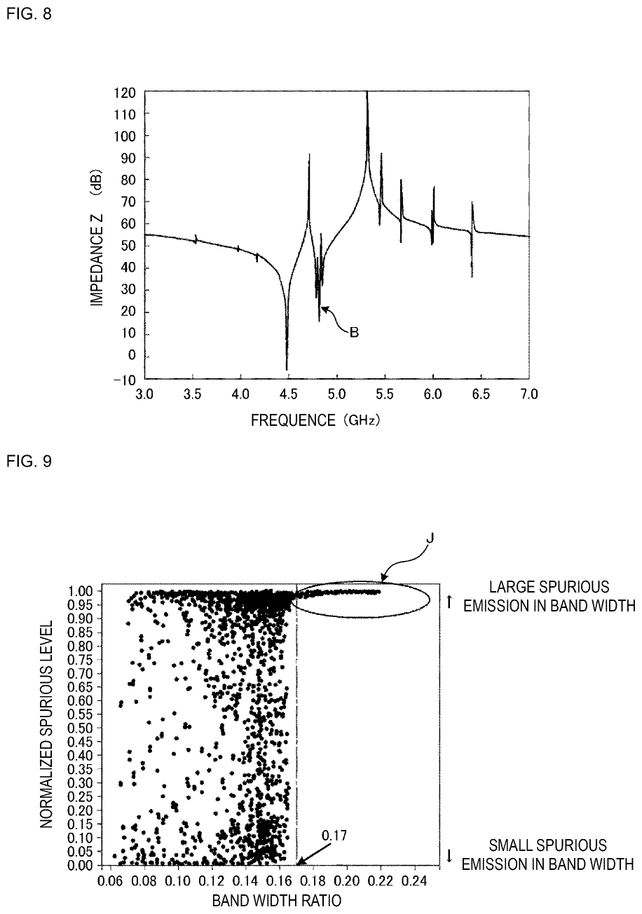

The acoustic wave device 10 preferably has a metallization ratio MR of the adjacent electrode fingers 31 and 32 to the intersecting region C that satisfies MR≤about 1.75 (d/p)+0.075, for example. In this case, the acoustic wave device 10 can effectively reduce or prevent a spurious emission. This mechanism is described with reference to FIG. 8 and FIG. 9.

FIG. 8 is a reference graph of an example of resonance characteristics of the acoustic wave device according to the first example embodiment. As illustrated in FIG. 8, a spurious emission indicated by arrow B appears between the resonant frequency and the anti-resonant frequency. Here, d/p=about 0.08, and LiNbO₃ has Euler angles (0°, 0°, 90°). The metallization ratio MR is about 0.35.

The metallization ratio MR is described with reference to FIG. 1. In the electrode structure in FIG. 1, when attention is directed to a pair of electrode fingers 31 and 32, the pair of electrode fingers 31 and 32 is assumed to be provided. In this case, the portion surrounded by a dot-and-dash line defines the intersecting region C. When the electrode finger 31 and the electrode finger 32 are viewed in the direction perpendicular or substantially perpendicular to the extension direction of the electrode finger 31 and the electrode finger 32, more specifically, viewed in a facing direction, the intersecting region C is a region of the electrode finger 31 overlapping the electrode finger 32, a region of the electrode finger 32 overlapping the electrode finger 31, and a region in the region between the electrode fingers 31 and 32 overlapping the electrode fingers 31 and 32. A ratio of the area of the electrode fingers 31 and 32 in the intersecting region C to the area of the intersecting region C corresponds to the metallization ratio MR. More specifically, the metallization ratio MR is a ratio of the area of the metallization portion to the area of the intersecting region C.

When multiple pairs of electrode fingers 31 and 32 are provided, the metallization ratio MR may be a ratio of the metallization portions included in all of the intersecting regions C to the sum of areas of the intersecting regions C.

FIG. 9 is a graph of a relationship, in the acoustic wave device according to the first example embodiment, between the band width ratio in a structure including a large amount of acoustic wave resonators and a phase rotation amount of the spurious impedance, normalized to about 180 degrees as the level of the spurious emission. The band width ratio is adjusted by changing, in various manners, the film thickness of the piezoelectric layer 20 and the dimensions of the electrode fingers 31 and 32. FIG. 9 illustrates the result caused when, for example, the piezoelectric layer 20 made of LiNbO₃ with a Z-cut is used, but the same or similar results are obtained when the piezoelectric layer 20 with another cut-angle is used.

In the region surrounded by an ellipse J in FIG. 9, the spurious emission is as large as about 1.0. As is clear from FIG. 9, when the band width ratio exceeds about 0.17, more specifically, exceeds about 17%, large spurious emissions with spurious levels greater than or equal to about 1 appear in the pass band regardless of when parameters of the band width ratio are changed. More specifically, a large spurious emission indicated by arrow B appears in the band width, as in the resonance characteristics illustrated in FIG. 8. Thus, the band width ratio is, for example, preferably less than or equal to about 17%. In this case, a spurious emission can be reduced by adjusting the film thickness of the piezoelectric layer 20 or the dimensions of the electrode fingers 31 and 32.

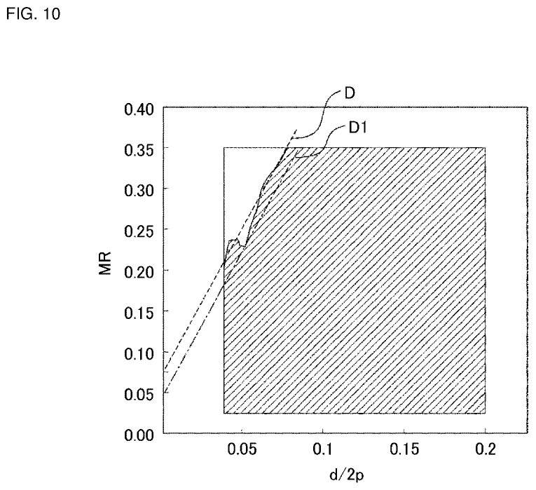

FIG. 10 is a graph of the relationship between d/2p, the metallization ratio MR, and a band width ratio. Acoustic wave devices 10 according to the first example embodiment with different d/2p and different MR were provided, and the band width ratio of each acoustic wave device 10 was measured. The hatched portion on the right of the broken line D in FIG. 10 is the region with a band width ratio less than or equal to about 17%. The boundary between the hatched region and an unhatched region is expressed as MR=about 3.5 (d/2p)+0.075. More specifically, MR=about 1.75 (d/p)+0.075. Preferably, for example, MR ≤about 1.75 (d/p)+0.075. In this case, the band width ratio is more likely to be less than or equal to about 17%, for example. The region on the right of dot-and-dash line D1 in FIG. 10, for example, where MR=about 3.5 (d/2p)+0.05 is more preferable. More specifically, when MR≤about 1.75 (d/p)+0.05, the band width ratio is reliably reduced to less than or equal to about 17%, for example.

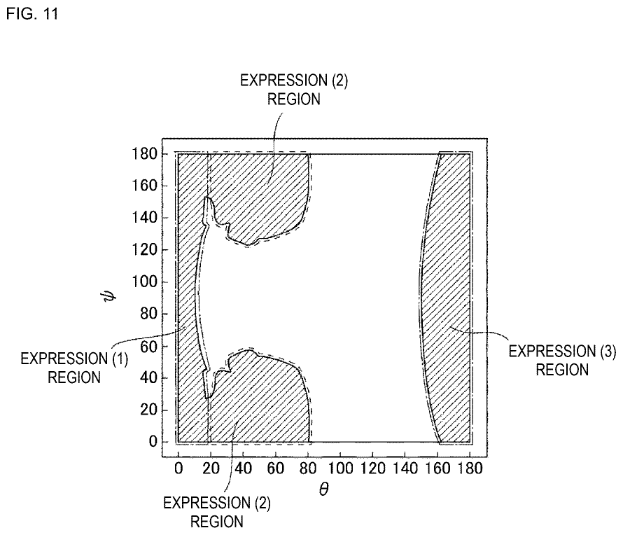

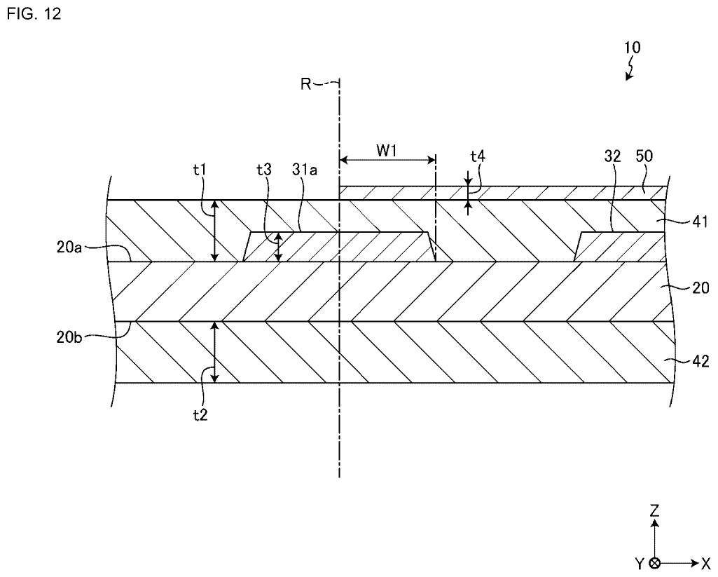

FIG. 11 is a graph of a map of the band width ratio with respect to Euler angles (0°, θ, ψ) of LiNbO₃ when d/p is infinitely approximated to zero. The hatched portions in FIG. 11 are regions in which a band width ratio at least greater than or equal to about 5% is obtained. When the range of the region is approximated, the range is expressed by Formula (1), Formula (2), and Formula (3):

$$( 0 ° \pm 10 ° , 0 ° to 20 ° , any ψ ) , \qquad Formula ( 1 )$$

$$( 0 ° \pm 10 ° , 20 ° to 80 ° , 0 ° to 60 ° {( 1 - {( θ - 50 )}^{2} / 900 )}^{1 / 2} ) or ( 0 ° \pm 10 ° , 20 ° to 80 ° , \{ 180 ° - 60 ° {( 1 - {( θ - 50 )}^{2} / 900 )}^{1 / 2} \} to 180 ° ) , and \qquad Formula ( 2 )$$

$$Formula ( 3 )$$

$$( 0 ° \pm 10 ° , \{ 180 ° - 30 ° {( 1 - {( ψ - 90 )}^{2} / 8100 )}^{1 / 2} \} to 180 ° , any ψ ) .$$

Thus, in the range of Euler angles in Formula (1), Formula (2), or Formula (3), the band width ratio can preferably be large.

Subsequently, the structure of the load film 50 is described in detail. FIG. 12 is an enlarged cross-sectional view of a region A in FIG. 2. In FIG. 12, a portion of the load film 50 that overlaps the first electrode finger 31a located outermost in the arrangement direction of the multiple electrode fingers 31 and 32 is described, but a portion of the load film 50 that overlaps the second electrode finger 32a located outermost and away from the first electrode finger 31a has a line symmetric positional relationship with the portion overlapping the first electrode finger 31a. More specifically, the description on the first electrode finger 31a is also applicable to the description on the second electrode finger 32a.

As illustrated in FIG. 12, the load film 50 is disposed on the first protection film 41, and overlaps a portion of the first electrode finger 31a. More specifically, the load film 50 is not disposed at a portion of the region overlapping the first electrode finger 31a. In the present example embodiment, the upper surface of the first protection film 41 is flat. More specifically, the upper surface of the first protection film 41 is substantially coplanar over the region where the electrode fingers 31 and 32 are disposed and the region where the electrode fingers 31 and 32 are not disposed.

The load film 50 protrudes from the upper surface of the first protection film 41. In the region overlapping the first electrode finger 31a, a level difference is provided by the load film 50 and the first protection film 41. More specifically, a region in which the first electrode finger 31a, the first protection film 41, and the load film 50 are laminated in this order, a region in which the first electrode finger 31a and the first protection film 41 are laminated in this order, and a region in which the first protection film 41 is laminated are provided over the first main surface 20a of the piezoelectric layer 20. In the region overlapping the first electrode finger 31a, a level difference is provided by a portion in which the load film 50 and the first protection film 41 are laminated and a portion in which the first protection film 41 is disposed and the load film 50 is not disposed.

The load film 50 is disposed inward from the first electrode finger 31a in the arrangement direction of the multiple electrode fingers 31 and 32. A first side surface of the load film 50 is disposed to overlap a middle point of the first electrode finger 31a in the width direction. More specifically, the load film 50 includes a superposing region that superposes a portion of the first electrode finger 31a. A width W1 of the superposing region of the load film 50 is, for example, about 0.3 μm.

In the present example embodiment, a film thickness t4 of the load film 50 is, for example, about 55 nm. As described above, the film thickness t1 of the first protection film 41 and the film thickness t2 of the second protection film 42 are, for example, about 142 nm, and a film thickness t3 of the IDT electrode 30 is, for example, about 112 nm. The film thickness t1 of the first protection film 41 is greater than the film thickness t4 of the load film 50, and greater than the film thickness t3 of the IDT electrode 30.

The load film 50 is made of a different material from the first protection film 41. In the present example embodiment, for example, the load film 50 is made of tantalum oxide (Ta₂O₅). The first protection film 41 is made silicon oxide (SiO₂). More specifically, in the load film 50 according to the first modified example, the density in the present example embodiment indicates the physical property value unique to the material unless otherwise particularly noted. The load film 50 and the first protection film 41 may be made of the same material, or the load film 50 and the first protection film 41 may be made of the same material, but may have different densities. For example, when the load film 50 is formed by vapor deposition, the actual density of the load film 50 is smaller than the density of the first protection film 41.

The load film 50 thus overlaps a portion of the first electrode finger 31a. Thus, in the region of the load film 50 overlapping the first electrode finger 31a located outermost in the arrangement direction of the multiple electrode fingers 31 and 32, a region where only the first protection film 41 is laminated has different acoustic impedance from the region in which the load film 50 and the first protection film 41 are laminated. Thus, an acoustic reflection plane R is provided at a level difference portion (portion overlapping the side surface of the load film 50) between the load film 50 and the first protection film 41.

The acoustic wave excited by the piezoelectric layer 20 is thus reflected by the acoustic reflection plane R. The acoustic wave device 10 can thus reduce or prevent leakage of acoustic waves in the arrangement direction of the multiple electrode fingers 31 and 32.

FIG. 13 is a graph of an example of admittance characteristics of the acoustic wave device according to the first example embodiment. More specifically, FIG. 13 is a graph of a real part of admittance of the acoustic wave device according to the first example embodiment, more specifically, a conductance component. The admittance characteristics illustrated in FIG. 13 are simulation results of the admittance characteristics of the acoustic wave device 10 according to the first example embodiment. FIG. 13 also illustrates simulation results of admittance characteristics of an acoustic wave device according to a comparative example. An acoustic wave device according to the comparative example does not include the load film 50, as compared with the acoustic wave device according to the first example embodiment.

As illustrated in FIG. 13, in the acoustic wave device according to the comparative example, ripples are caused in a frequency range different from the resonant frequency. In the comparative example, particularly, large ripples indicated by dotted lines E1 and E2 are caused. In contrast, in the acoustic wave device 10 according to the first example embodiment in which the load film 50 is disposed to overlap a portion of the first electrode finger 31a, ripples indicated by dotted lines E1 and E2 are reduced further than the acoustic wave device according to the comparative example. In the acoustic wave device 10 according to the first example embodiment, the peak width of the resonant frequency is narrower than that in the acoustic wave device according to the comparative example, and propagation loss is thus reduced, and leakage of acoustic waves is reduced or prevented.

The shape, the width, and the film thickness of each of the load film 50, the first protection film 41, and the IDT electrode 30 are mere examples, and may be changed as appropriate. For example, the side surfaces of the load film 50 may be tapered.

FIG. 14 is a graph of an example of admittance characteristics of an acoustic wave device according to a first modified example of the first example embodiment. The acoustic wave device according to the first modified example differs from the acoustic wave device 10 according to the first example embodiment in that the load film 50 is, for example, made of carbon-doped silicon oxide (SiOC). More specifically, the load film 50 according to the first modified example is made of a material with a lower density than silicon oxide used for the first protection film 41. The film thickness t4 of the load film 50 is, for example, about 45 nm. The width W1 of the load film 50 and the structures of, for example, the first protection film 41 and the IDT electrode 30 are the same or substantially the same as those in the first example embodiment.

FIG. 14 reveals that the acoustic wave device according to the first modified example reduces a ripple indicated by a dotted line E2, as compared with a comparative example, in the same manner as the acoustic wave device 10 according to the first example embodiment. Also in the first modified example, the peak width associated with the resonant frequency is narrower, and propagation loss is thus reduced.

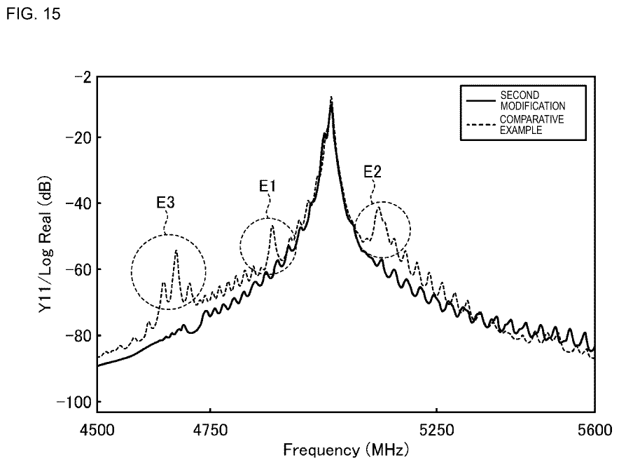

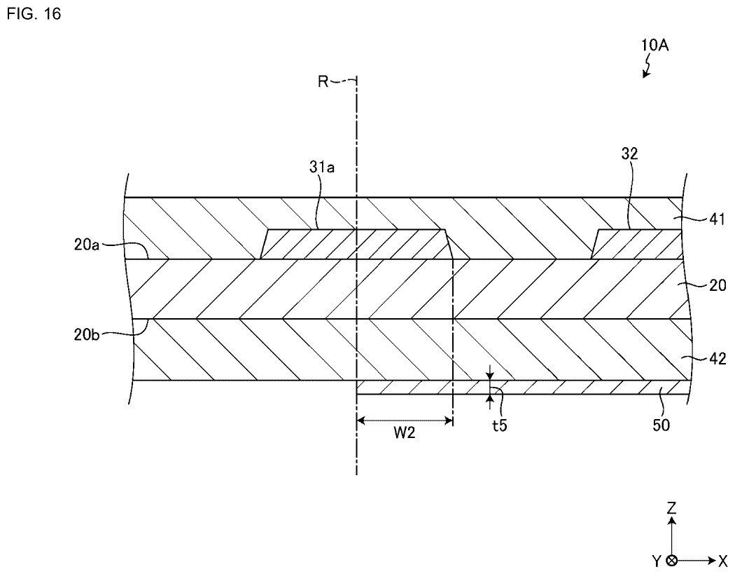

FIG. 15 is a graph of an example of admittance characteristics of an acoustic wave device according to a second modified example of the first example embodiment. The acoustic wave device according to the second modified example differs from the acoustic wave device 10 according to the first example embodiment in that the load film 50 is made silicon nitride (SiN). More specifically, the load film 50 according to the second modified example is made of a material with greater hardness than silicon oxide used for the first protection film 41. The film thickness t4 of the load film 50 is, for example, about 65 nm. The width W1 of the load film 50 and the structures of, for example, the first protection film 41 and the IDT electrode 30 are the same or substantially the same as those in the first example embodiment. “The hardness” in the present example embodiment indicates a physical property value unique to the material unless otherwise particularly noted.

FIG. 15 reveals that the acoustic wave device according to the second modified example reduces ripples indicated by dotted lines E1 and E2, as compared with the acoustic wave device according to the comparative example. The acoustic wave device according to the second modified example also reduces a ripple indicated by a dotted line E3. The acoustic wave device according to the second modified example reduces ripples and propagation loss in the same manner as the acoustic wave device 10 according to the first example embodiment.

The material of the load film 50 according to the first modified example and the second modified example is a mere example, and is not limited to this. The material of the load film 50 includes, for example, at least one of SiOC, SiO₂, SiN, Ta₂O₅, AlN, Al₂O₃, HfO₂, Nb₂O₅, or WO.

FIG. 16 is a cross-sectional view of an acoustic wave device according to a second example embodiment of the present invention. In the acoustic wave device according to each of the first example embodiment, the first modified example, and the second modified example, the load film 50 is disposed on the first protection film 41 at a portion closer to the first main surface 20a of the piezoelectric layer 20, but the present invention is not limited to this structure. As illustrated in FIG. 16, in an acoustic wave device 10A according to a second example embodiment, the load film 50 is disposed on a lower surface of the second protection film 42 at a portion closer to the second main surface 20b of the piezoelectric layer 20. In other words, the load film 50 is not located closer to the first main surface 20a of the piezoelectric layer 20, and the upper surface of the first protection film 41 is flat. The lower surface of the second protection film 42 is a surface of the second protection film 42 facing the support substrate 11 (refer to FIG. 2).

The lower surface of the second protection film 42 is flat along the second main surface 20b of the piezoelectric layer 20. The load film 50 is disposed at the lower surface of the second protection film 42 to overlap a portion of the first electrode finger 31a. In the present example embodiment, the region overlapping the first electrode finger 31a includes a region in which the second protection film 42 and the load film 50 are laminated on the second main surface 20b of the piezoelectric layer 20 and a region in which the second protection film 42 is disposed on the second main surface 20b of the piezoelectric layer 20 and the load film 50 is not disposed. Thus, in the region overlapping the first electrode finger 31a, a level difference is provided by the load film 50 and the second protection film 42.

In the second example embodiment, the load film 50 is made of a different material from the first protection film 41 and the second protection film 42, for example, silicon nitride (SiN). The width W2 of the superposing region of the load film 50 is, for example, about 0.3 μm. A film thickness t5 of the load film 50 is, for example, about 65 nm.

The structure of the load film 50 in a plan view is the same or substantially the same as that of the load film 50 illustrated in FIG. 2, and not repeatedly described. Although not illustrated, the load film 50 is also disposed at a portion overlapping a portion of the second electrode finger 32a (refer to FIG. 2) on the opposite side in the arrangement direction of the multiple electrode fingers 31 and 32.

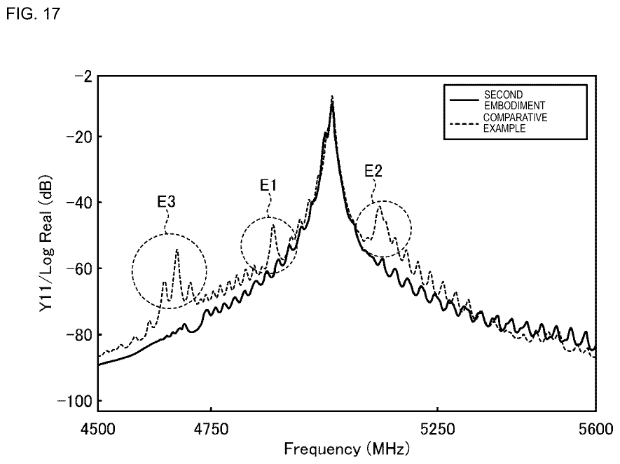

FIG. 17 is a graph of an example of admittance characteristics of the acoustic wave device according to the second example embodiment. As illustrated in FIG. 17, the acoustic wave device 10A according to the second example embodiment in which the load film 50 is disposed at a portion closer to the second main surface 20b of the piezoelectric layer 20 reduces ripples indicated by dotted lines E1, E2, and E3 in the same manner as the acoustic wave device 10 according to the first example embodiment, as compared with the comparative example. Also in the second example embodiment, the peak width associated with the resonant frequency is narrower, and propagation loss is thus reduced. In the acoustic wave device according to the second example embodiment, the load film 50 is not disposed on the first protection film 41 as compared with the first example embodiment. Thus, the acoustic wave device can easily adjust the resonant frequency by changing the film thickness of the first protection film 41.

In the second example embodiment, the first modified example and the second modified example may be combined as appropriate. More specifically, the load film 50 may be disposed at the lower surface of the second protection film 42, and made of any material different from that of the second protection film 42. Alternatively, the load film 50 may be disposed at the lower surface of the second protection film 42, and the film thickness of the first protection film 41 and the second protection film 42 may be smaller than the film thickness of the piezoelectric layer 20.

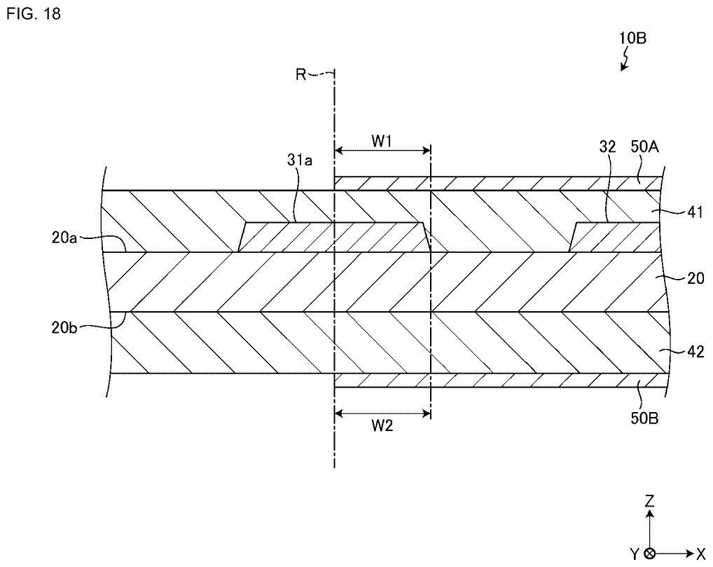

FIG. 18 is a cross-sectional view of an acoustic wave device according to a third example embodiment of the present invention. As illustrated in FIG. 18, in an acoustic wave device 10B according to a third example embodiment, the load film 50 is disposed on each of the first protection film 41 and the lower surface of the second protection film 42 (a surface facing the support substrate 11 (refer to FIG. 2)). In the description below, the load film 50 disposed on the first protection film 41 is referred to as an upper load film 50A, and the load film 50 disposed on the lower surface of the second protection film 42 is referred to as a lower load film 50B. When the upper load film 50A and the lower load film 50B do not need to be distinguished from each other, they are simply referred to as the load films 50.

In the present example embodiment, the upper load film 50A and the lower load film 50B are made of the same material, such as, for example, silicon nitride (SiN). The upper load film 50A and the lower load film 50B overlap each other, and overlap a portion of the first electrode finger 31a.

The width W1 of the superposing region of the upper load film 50A and the width W2 of the superposing region of the lower load film 50B are, for example, about 0.3 μm. The film thickness t4 of the upper load film 50A and the film thickness t5 of the lower load film 50B are, for example, about 40 nm.

In the above example, the upper load film 50A and the lower load film 50B are made of the same material and have the same or substantially the same shape, but the present invention is not limited to this example. The upper load film 50A and the lower load film 50B may be made of different materials and have different shapes.

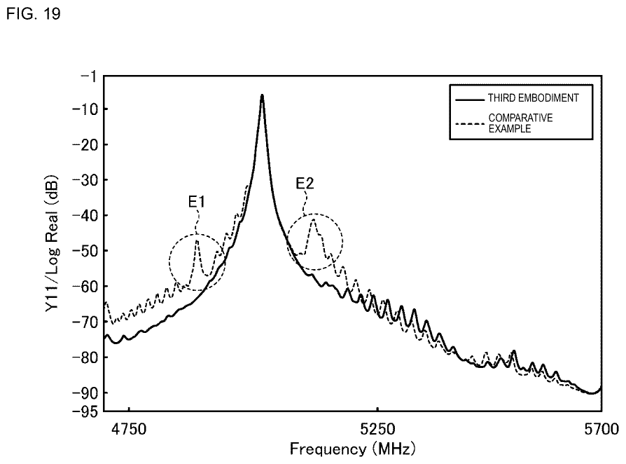

FIG. 19 is a graph of an example of admittance characteristics of the acoustic wave device according to the third example embodiment. As illustrated in FIG. 19, the acoustic wave device 10B according to the third example embodiment in which the load films 50 are disposed on both the first main surface 20a and the second main surface 20b of the piezoelectric layer 20 preferably reduces ripples indicated by dotted lines E1, and E2 as compared with the comparative example. Also in the third example embodiment, the peak width associated with the resonant frequency is narrower, and propagation loss is thus reduced.

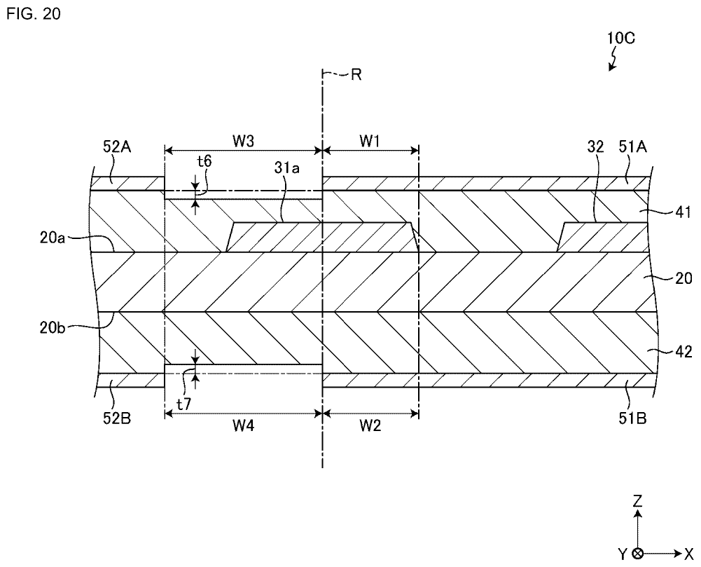

FIG. 20 is a cross-sectional view of an acoustic wave device according to a fourth example embodiment of the present invention. As illustrated in FIG. 20, in an acoustic wave device 10C according to the fourth example embodiment, the load film 50 is disposed on each of the first protection film 41 and the lower surface of the second protection film 42 (a surface facing the support substrate 11 (refer to FIG. 2)). In the description below, the load film 50 disposed on the first protection film 41 is referred to as an upper load film 50A, and the load film 50 disposed on the lower surface of the second protection film 42 is referred to as a lower load film 50B. When the upper load film 50A and the lower load film 50B do not need to be distinguished from each other, they are simply referred to as the load films 50. The upper load film 50A includes an inner load film 51A and an outer load film 52A, and the lower load film 50B includes an inner load film 51A and an outer load film 52B.

In the present example embodiment, the inner load film 51A and the inner load film 51B are made of the same material, such as, for example, silicon nitride (SiN). The inner load films 51A and 51B overlap with each other, and each overlap with a portion of the first electrode finger 31a.

The width W1 of the superposing region of the inner load film 51A and the width W2 of the superposing region of the inner load film 51B are, for example, about 0.3 μm. The film thickness t4 of the inner load film 51A and the film thickness t5 of the inner load film 51B are, for example, about 30 nm.

The inner load films 51A and 51B are made of the same material and have the same or substantially the same shape, but the present invention is not limited to this example. The inner load films 51A and 51B may be made of different materials and have different shapes, as described later.

The outer load films 52A and 52B are located in a region outward from the inner load films 51A and 51B in the arrangement direction, and not overlapping the IDT electrode 30 (electrode fingers 31 and 32). The outer load film 52A is disposed on the first protection film 41 at the same layer as the inner load film 51A, and spaced apart from the inner load film 51A. Similarly, the outer load film 52B is disposed under the second protection film 42 at the same layer as the inner load film 51B, and spaced apart from the inner load film 51B. The outer load films 52A and 52B are made of, for example, silicon nitride (SiN), in the same manner as the inner load films 51A and 51B. A distance W3 between the inner load film 51A and the outer load film 52A and a distance W4 between the inner load film 51B and the outer load film 52B are, for example, about 0.6 μm. The film thickness of the outer load films 52A and 52B is, for example, about 30 nm, in the same manner as the film thicknesses t4 and t5 of the inner load films 51A and 51B.

In the example in FIG. 20, the first protection film 41 and the second protection film 42 each include a recess on the surface facing the load film 50 at a portion overlapping a region between the inner load film 51 and the outer load film 52. Thus, in the region overlapping the first electrode finger 31a, a level difference is provided by the inner load film 51A and the first protection film 41, and a level difference is provided by the inner load film 51B and the second protection film 42. Depths t6 and t7 of the recesses on the first protection film 41 and the second protection film 42 are, for example, about 20 nm.

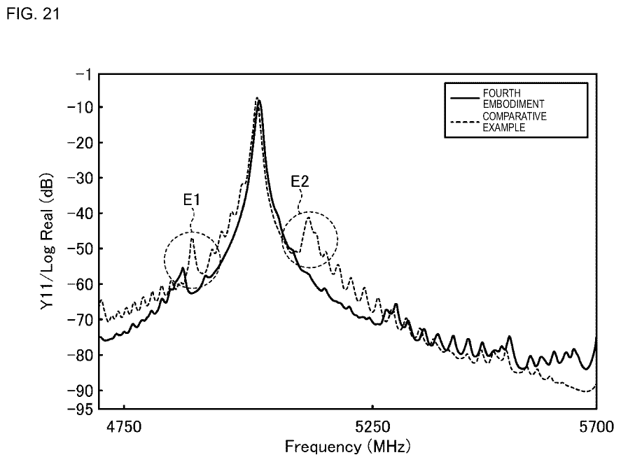

FIG. 21 is a graph of an example of admittance characteristics of an acoustic wave device according to the fourth example embodiment. FIG. 21 reveals that an acoustic wave device 10C according to the fourth example embodiment in which the load films 50 are disposed on both the first main surface 20a and the second main surface 20b of the piezoelectric layer 20 preferably reduces ripples indicated by dotted lines E1, and E2 as compared with the comparative example. Also in the acoustic wave device 10C according to the fourth example embodiment, the peak width associated with the resonant frequency is narrower, and propagation loss is thus reduced.

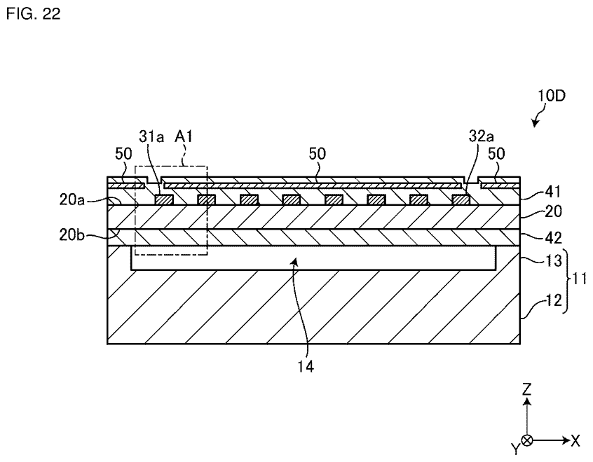

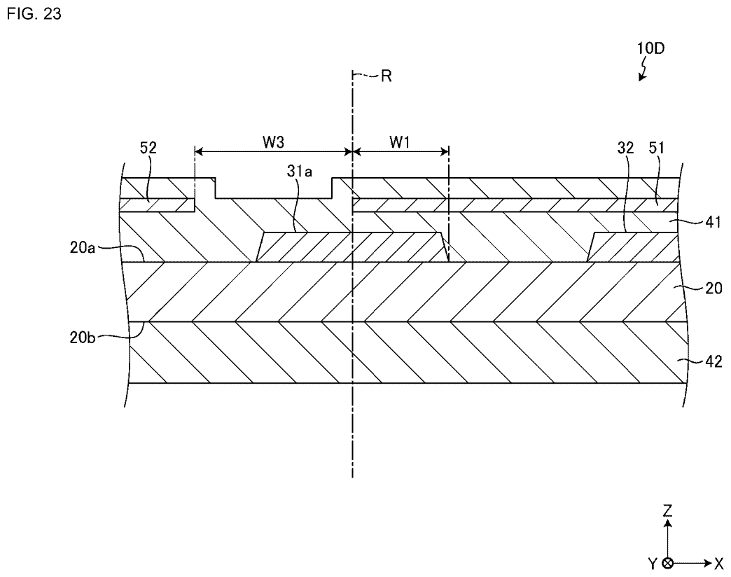

FIG. 22 is a cross-sectional view of an acoustic wave device according to a fifth example embodiment of the present invention. FIG. 23 is an enlarged cross-sectional view of a region A1 in FIG. 22. As illustrated in FIG. 22 and FIG. 23, in the acoustic wave device 10D according to the fifth example embodiment, the load film 50 is spaced apart from the multiple electrode fingers 31 and 32 and the first main surface 20a. The upper surface of the first protection film 41 has unevenness to reflect the shape of the load film 50. The load film 50 includes an inner load film 51 and an outer load film 52.

The inner load film 51 is disposed in the first protection film 41. More specifically, the first protection film 41 is disposed between the first main surface 20a of the piezoelectric layer 20 and the multiple electrode fingers 31 and 32 and the inner load film 51, and covers the side surfaces and the upper surface (a surface facing away from the piezoelectric layer 20) of the inner load film 51.

As in the case of the first example embodiment, the inner load film 51 is made of, for example, tantalum oxide (Ta₂O₅). The width W1 of the superposing region of the inner load film 51 is, for example, about 0.3 μm. The film thickness of the inner load film 51, and the structures of, for example, the first protection film 41, the second protection film 42, and the IDT electrode 30 are the same or substantially the same as those in the first example embodiment. The distance between the inner load film 51 and the second main surface 20b of the piezoelectric layer 20 in a direction perpendicular or substantially perpendicular to the second main surface 20b of the piezoelectric layer 20 is, for example, about 320 nm.

The outer load film 52 is disposed in a region outward from the inner load film 51 in the arrangement direction and not overlapping the IDT electrode 30 (electrode fingers 31 and 32). The outer load film 52 is disposed in the first protection film 41 at the same layer as the inner load film 51, and spaced apart from the inner load film 51. The outer load film 52 is made of, for example, tantalum oxide (Ta₂O₅), in the same manner as the inner load film 51. The distance W3 between the inner load film 51 and the outer load film 52 is, for example, about 0.6 μm. The film thickness of the outer load film 52 is, for example, about 55 nm, which is the same or substantially the same as the film thickness t4 of the inner load film 51. However, the distance is not limited to this, and the material and the film thickness of the outer load film 52 may be different from the material and the film thickness t4 of the inner load film 51.

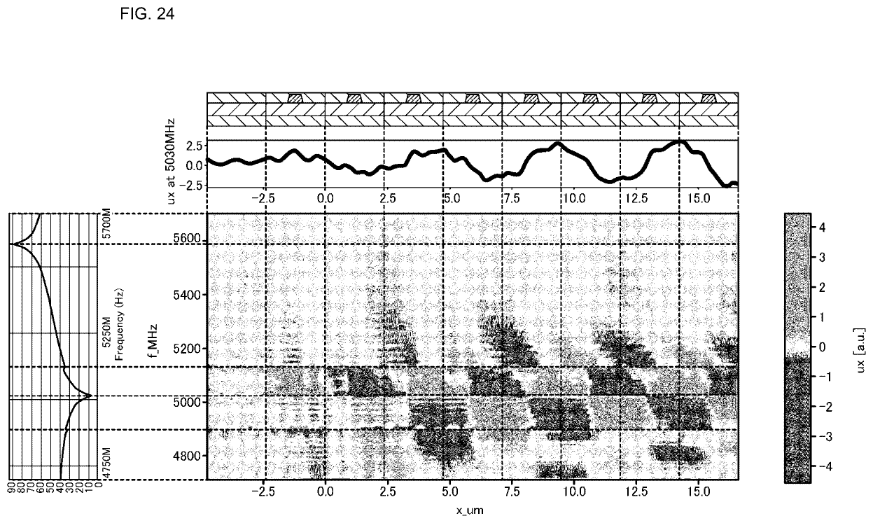

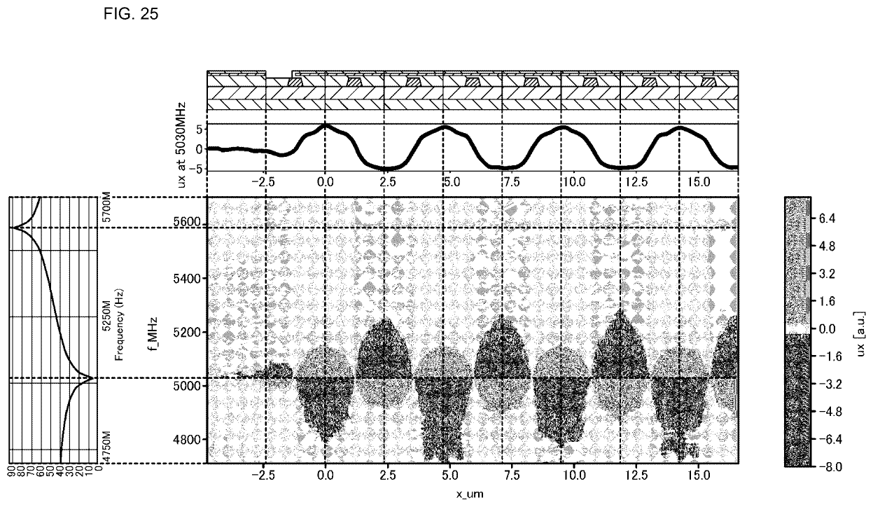

FIG. 24 is a graph of distribution of a vibration mode of the acoustic wave device according to the fifth example embodiment. FIG. 25 is a graph of distribution of a vibration mode of an acoustic wave device according to a comparative example. An acoustic wave device according to the comparative example illustrated in FIG. 25 has a structure not including the load film 50, as compared with the acoustic wave device 10D according to the fifth example embodiment.

FIG. 24 and FIG. 25 illustrate distribution of the degree of displacement of the piezoelectric layer 20 in each of the fifth example embodiment and the comparative example, using the horizontal axis as the X direction (arrangement direction of the electrode fingers 31 and 32), and the vertical axis as the frequency. At upper portions in FIG. 24 and FIG. 25, the cross-sectional views of the acoustic wave devices corresponding to the X direction are schematically illustrated, and at the left portions in FIG. 24 and FIG. 25, the impedance characteristics of the acoustic wave devices are illustrated.

As illustrated in FIG. 25, in the acoustic wave device according to the comparative example, displacement in the X direction (X-direction positions of the loop and the node of displacement) has large dependence on frequency. For example, the X-direction position indicating the peak of displacement is shifted by the frequency, and the acoustic wave device fails in stable excitation between electrodes. When attention is directed to a predetermined X position (X=around 5.0 μm), the phase is inverted at the resonant frequency about 5030 MHz and at the frequencies about 4900 MHz and about 5120 MHz where ripples occur. In this manner, the acoustic wave device according to the comparative example may fail to obtain ideal excitation mode.

In contrast, as illustrated in FIG. 24, in the acoustic wave device 10D according to the fifth example embodiment, displacement in the X direction (X-direction positions of the loop and the node of displacement) does not have dependence on frequency. More specifically, the X-direction position indicating the peak of displacement is stably independent of frequency, and the acoustic wave device achieves stable excitation between electrodes. In addition, the degree of displacement (amplitude) is stable for each region between electrodes, without causing inversion of the phase at the resonant frequency and the frequency array at which ripples occur. As described above, a preferable excitation mode is obtained by simply disposing the load film 50 at a portion overlapping a portion of the first electrode finger 31a located outermost in the arrangement direction, as compared with the comparative example.

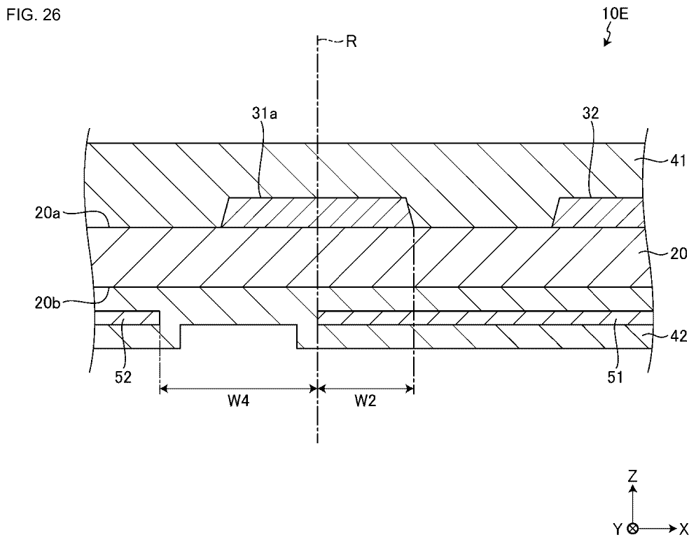

FIG. 26 is a cross-sectional view of an acoustic wave device according to a sixth example embodiment of the present invention. As illustrated in FIG. 26, in an acoustic wave device 10E according to the sixth example embodiment, the load film 50 is disposed over the second main surface 20b of the piezoelectric layer 20. More specifically, the load film 50 is disposed to face the second main surface 20b of the piezoelectric layer 20, and spaced apart from the second main surface 20b. The lower surface of the second protection film 42 has unevenness reflecting the shape of the load film 50. The load film 50 includes an inner load film 51 and an outer load film 52.

The inner load film 51 is disposed in the second protection film 42. More specifically, the second protection film 42 is disposed between the second main surface 20b of the piezoelectric layer 20 and the inner load film 51, and covers the side surfaces and the lower surface (a surface facing away from the piezoelectric layer 20) of the inner load film 51.

As in the case of the first example embodiment, the inner load film 51 is made of, for example, tantalum oxide (Ta₂O₅). The width W2 of the superposing region of the inner load film 51 is, for example, about 0.3 μm. The film thickness of the inner load film 51, and the structures of, for example, the first protection film 41, the second protection film 42, and the IDT electrode 30 are the same or substantially the same as those in the first example embodiment. The distance between the inner load film 51 and the second main surface 20b of the piezoelectric layer 20 in a direction perpendicular or substantially perpendicular to the second main surface 20b of the piezoelectric layer 20 is, for example, about 50 nm.

The outer load film 52 is disposed in a region outward from the inner load film 51 in the arrangement direction and not overlapping the IDT electrode 30 (electrode fingers 31 and 32). The outer load film 52 is disposed in the second protection film 42 at the same layer as the inner load film 51, and spaced apart from the inner load film 51. The outer load film 52 is made of, for example, tantalum oxide (Ta₂O₅), in the same manner as the inner load film 51. The distance W4 between the inner load film 51 and the outer load film 52 is, for example, about 0.6 μm. The film thickness of the outer load film 52 is, for example, about 55 nm, which is the same or substantially the same as the film thickness t5 of the inner load film 51. However, the present invention is not limited to this example, and the material and the film thickness of the outer load film 52 may be different from the material and the film thickness t4 of the inner load film 51.

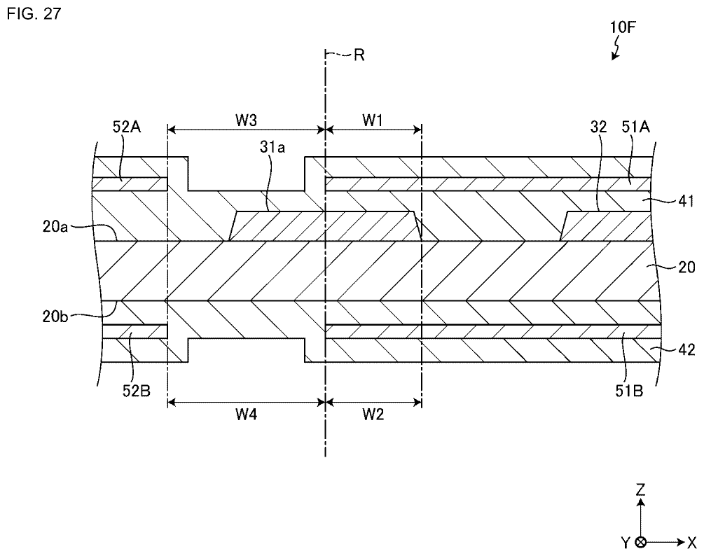

FIG. 27 is a cross-sectional view of an acoustic wave device according to a seventh example embodiment of the present invention. As illustrated in FIG. 27, in an acoustic wave device 10F according to the seventh example embodiment, the load films 50 are disposed over the first main surface 20a of the piezoelectric layer 20 and over the second main surface 20b of the piezoelectric layer 20. In the description below, the load film 50 disposed on the first protection film 41 is referred to as an upper load film 50A, and the load film 50 disposed on the lower surface of the second protection film 42 is referred to as a lower load film 50B. When the upper load film 50A and the lower load film 50B do not need to be distinguished from each other, they are simply referred to as the load films 50. The upper load film 50A is spaced apart from the multiple electrode fingers 31 and 32 and the first main surface 20a, and the lower load film 50B faces the second main surface 20b of the piezoelectric layer 20, and is spaced apart from the second main surface 20b. The upper load film 50A includes an inner load film 51A and an outer load film 52A, and the lower load film 50B includes an inner load film 51B and an outer load film 52B.

The inner load film 51A is disposed in the first protection film 41. The inner load film 51B is disposed in the second protection film 42. More specifically, the first protection film 41 is disposed between the first main surface 20a of the piezoelectric layer 20 and the multiple electrode fingers 31 and 32 and the inner load film 51a, and covers the side surfaces and the upper surface (a surface facing away from the piezoelectric layer 20) of the inner load film 51a. The second protection film 42 is disposed between the second main surface 20b of the piezoelectric layer 20 and the inner load film 51b, and covers the side surfaces and the lower surface (a surface facing away from the piezoelectric layer 20) of the inner load film 51bh. The upper surface of the first protection film 41 has unevenness reflecting the shape of the inner load film 51A. The upper surface of the second protection film 42 has unevenness reflecting the shape of the inner load film 51B.

As in the case of the first example embodiment, the inner load film 51A and the inner load film 51B are made of the same material, for example, tantalum oxide (Ta₂O₅). The width W1 of the superposing region of the inner load film 51A and the width W2 of the superposing region of the inner load film 51B are, for example, about 0.3 μm. The film thickness of the inner load film 51A and the inner load film 51B, and the structures of, for example, the first protection film 41, the second protection film 42, and the IDT electrode 30 are the same or substantially the same as those in the first example embodiment. The distance between the inner load film 51A and the first main surface 20a of the piezoelectric layer 20 and the distance between the inner load film 51B and the second main surface 20b of the piezoelectric layer 20 in a direction perpendicular or substantially perpendicular to the second main surface 20b of the piezoelectric layer 20 are, for example, about 50 nm.

The inner load films 51A and 51B are made of the same material and have the same or substantially the same shape, but the present invention is not limited to this example. The inner load films 51A and 51B may be made of different materials and have different shapes.

The outer load film 52A is disposed in the first protection film 41 at the same layer as the inner load film 51A, and spaced apart from the inner load film 51A. Similarly, the outer load film 52B is disposed in the second protection film 42 at the same layer as the inner load film 51B, and spaced apart from the inner load film 51B. The outer load films 52A and 52B are made of, for example, tantalum oxide (Ta₂O₅), in the same manner as the inner load films 51A and 51B. The distance W3 between the inner load film 51A and the outer load film 52A and the distance W4 between the inner load film 51B and the outer load film 52B are, for example, about 0.6 μm. The film thickness of the outer load films 52A and 52B is, for example, about 55 nm, which is the same or substantially the same as the film thicknesses t4 and t5 of the inner load films 51A and 51B. However, the present invention is not limited to this example, and the material and the film thickness of the outer load film 52 may be different from the material and the film thickness t4 of the inner load film 51.

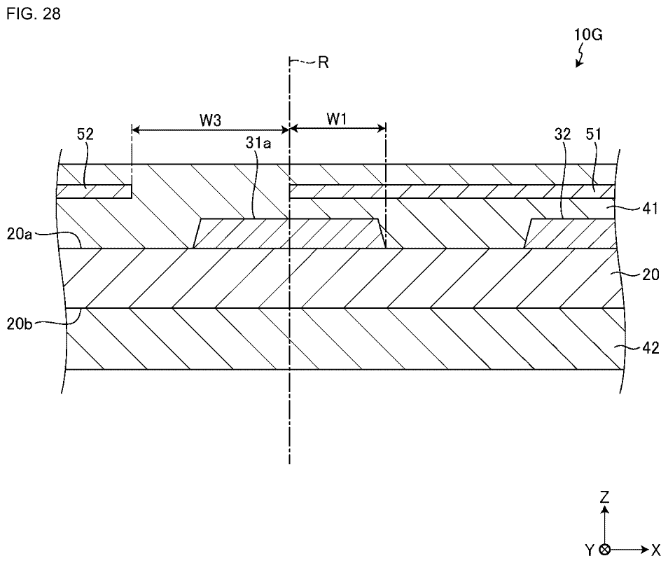

FIG. 28 is a cross-sectional view of an acoustic wave device according to an eighth example embodiment of the present invention. As illustrated in FIG. 28, in an acoustic wave device 10G according to the eighth example embodiment, the load film 50 is spaced apart from the multiple electrode fingers 31 and 32 and the first main surface 20a.

The load film 50 is disposed in the first protection film 41. More specifically, the first protection film 41 is disposed between the first main surface 20a of the piezoelectric layer 20 and the multiple electrode fingers 31 and 32 and the load film 50, and covers the side surfaces and the upper surface (a surface facing away from the piezoelectric layer 20) of the load film 50. In the present example embodiment, the upper surface of the first protection film 41 is flat. More specifically, the upper surface of the first protection film 41 is coplanar or substantially coplanar over the region where the load film 50 is disposed and a region where no load film 50 is disposed. The load film 50 includes an inner load film 51 and an outer load film 52.

As in the case of the first example embodiment, the inner load film 51 is made of, for example, tantalum oxide (Ta₂O₅). The width W1 of the superposing region of the inner load film 51 is, for example, about 0.3 μm. The film thickness of the inner load film 51, and the structures of, for example, the first protection film 41, the second protection film 42, and the IDT electrode 30 are the same or substantially the same as those in the first example embodiment. The distance between the inner load film 51 and the second main surface 20b of the piezoelectric layer 20 in a direction perpendicular to the second main surface 20b of the piezoelectric layer 20 is, for example, about 320 nm.

The outer load film 52 is disposed in a region outward from the inner load film 51 in the arrangement direction, and not overlapping the IDT electrode 30 (electrode fingers 31 and 32). The outer load film 52 is disposed in the first protection film 41 at the same layer as the inner load film 51, and spaced apart from the inner load film 51. The outer load film 52 is made of, for example, tantalum oxide (Ta₂O₅), in the same manner as the inner load film 51. The distance W3 between the inner load film 51 and the outer load film 52 is, for example, about 0.6 μm. The film thickness of the outer load film 52 is 55 nm, which is the same or substantially the same as the film thickness t5 of the inner load film 51.

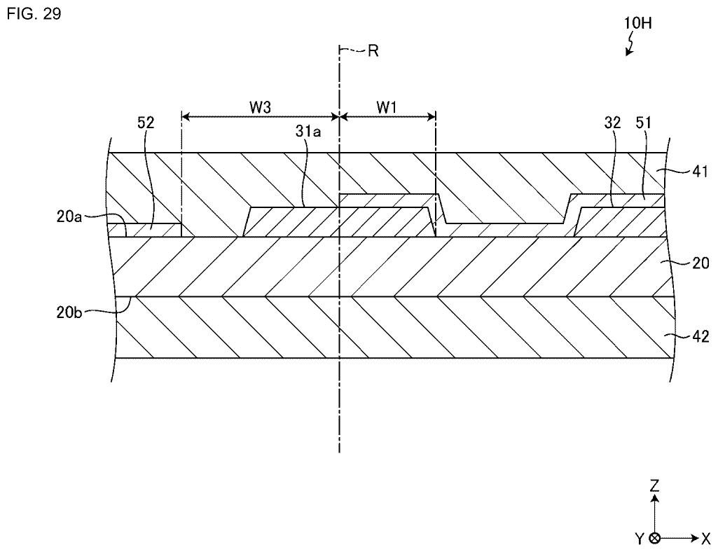

FIG. 29 is a cross-sectional view of an acoustic wave device according to a ninth example embodiment of the present invention. As illustrated in FIG. 29, in an acoustic wave device 10H according to the ninth example embodiment, the load film 50 is disposed on the first electrode finger 31a located outermost. More specifically, the load film 50 extends over the upper surface and the side surface of the first electrode finger 31a, and the first main surface 20a of the piezoelectric layer 20 at a portion where the electrode fingers 31 and 32 are not disposed. The load film 50 is disposed to follow the level difference provided by the piezoelectric layer 20 and the first electrode finger 31a. The load film 50 includes an inner load film 51 and an outer load film 52.

The inner load film 51 is made of, for example, tantalum oxide (Ta₂O₅). The width W1 of the superposing region of the inner load film 51 is, for example, about 0.3 μm. The film thickness of the inner load film 51 is, for example, about 55 nm. As in the case of the first example embodiment, the film thickness of the first protection film 41 and the film thickness of the second protection film 42 are, for example, about 142 nm, and the film thickness of the IDT electrode 30 is, for example, about 112 nm. In the present example embodiment, the upper surface of the first protection film 41 is flat. More specifically, the upper surface of the first protection film 41 is coplanar or substantially coplanar over the region where the inner load film 51 is disposed and a region where the inner load film 51 is not disposed.

The first protection film 41 is disposed on the first main surface 20a of the piezoelectric layer 20 while covering the inner load film 51 and the IDT electrode 30. In the present example embodiment, the upper surface of the inner load film 51 is covered with the first protection film 41. The region overlapping the first electrode finger 31a includes a portion where the inner load film 51 and the first protection film 41 are disposed and a portion where the first protection film 41 is disposed and the inner load film 51 is not disposed.

The outer load film 52 is disposed in a region outward from the inner load film 51 in the arrangement direction and not overlapping the IDT electrode 30 (electrode fingers 31 and 32). The outer load film 52 is disposed over the first main surface 20a at the same layer as the inner load film 51, and spaced apart from the inner load film 51. The outer load film 52 is made of, for example, tantalum oxide (Ta₂O₅), in the same manner as the inner load film 51. The distance W3 between the inner load film 51 and the outer load film 52 is, for example, about 0.6 μm. The film thickness of the outer load film 52 is, for example, about 55 nm, which is the same or substantially the same as the film thickness t5 of the inner load film 51.

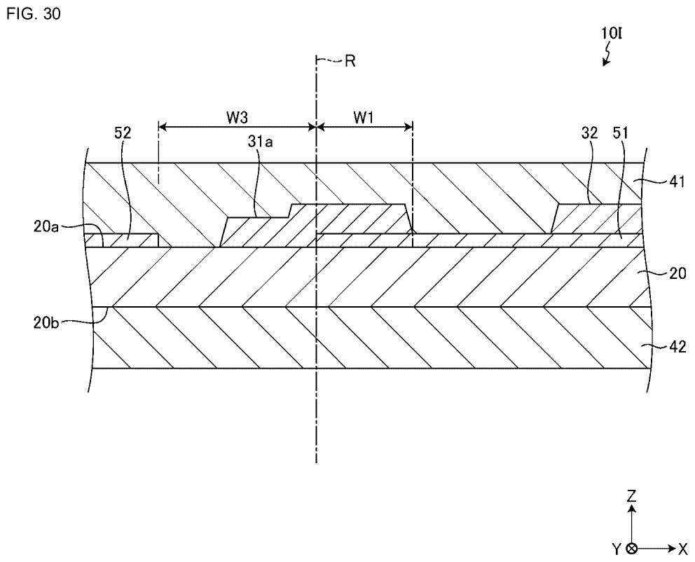

FIG. 30 is a cross-sectional view of an acoustic wave device according to a tenth example embodiment of the present invention. As illustrated in FIG. 30, in an acoustic wave device 10I according to the tenth example embodiment, the load film 50 is disposed at the first main surface 20a of the piezoelectric layer 20. The first protection film 41 and the first electrode finger 31a are disposed at the first main surface 20a of the piezoelectric layer 20 while covering the load film 50. The upper surface of the first protection film 41 flatly extends over a region overlapping the load film 50 and a region not overlapping the load film 50. In the present example embodiment, the load film 50 is not disposed over the second main surface 20b of the piezoelectric layer 20, and the lower surface of the second protection film 42 is flatly disposed. The load film 50 includes an inner load film 51 and an outer load film 52.

The inner load film 51 overlaps a portion of the first electrode finger 31a. In the tenth example embodiment, the inner load film 51 is made of a different material from the first protection film 41 and the second protection film 42, for example, tantalum oxide (Ta₂O₅). The width W2 of the superposing region of the inner load film 51 is, for example, about 0.3 μm. The film thickness t5 of the inner load film 51 is, for example, about 55 nm.

The outer load film 52 is disposed in a region outward from the inner load film 51 in the arrangement direction and not overlapping the IDT electrode 30 (electrode fingers 31 and 32). The outer load film 52 is disposed over the first main surface 20a at the same layer as the inner load film 51, and spaced apart from the inner load film 51. The outer load film 52 is made of, for example, tantalum oxide (Ta₂O₅), in the same manner as the inner load film 51. The distance W3 between the inner load film 51 and the outer load film 52 is, for example, about 0.6 μm. The film thickness of the outer load film 52 is, for example, about 55 nm, which is the same or substantially the same as the film thickness t5 of the inner load film 51.

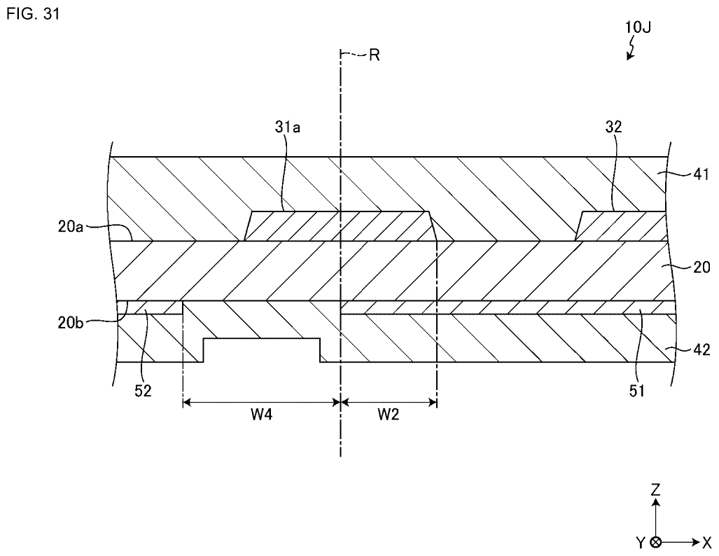

FIG. 31 is a cross-sectional view of an acoustic wave device according to an eleventh example embodiment of the present invention. As illustrated in FIG. 31, in an acoustic wave device 10J according to the eleventh example embodiment, the load film 50 is disposed at the second main surface 20b of the piezoelectric layer 20. The second protection film 42 is disposed at the second main surface 20b of the piezoelectric layer 20 while covering the load film 50. The lower surface of the second protection film 42 has unevenness reflecting the shape of the load film 50. In the present example embodiment, the load film 50 is not disposed over the first main surface 20a of the piezoelectric layer 20, and the upper surface of the first protection film 41 is flat. The load film 50 includes an inner load film 51 and an outer load film 52.

The inner load film 51 overlaps a portion of the first electrode finger 31a. In the eleventh example embodiment, the inner load film 51 is made of a different material from the first protection film 41 and the second protection film 42, for example, tantalum oxide (Ta₂O₅). The width W2 of the superposing region of the inner load film 51 is, for example, about 0.3 μm. The film thickness t5 of the inner load film 51 is, for example, about 55 nm.

The outer load film 52 is disposed in a region outward from the inner load film 51 in the arrangement direction and not overlapping the IDT electrode 30 (electrode fingers 31 and 32). The outer load film 52 is disposed under the second main surface 20b at the same layer as the inner load film 51, and spaced apart from the inner load film 51. The outer load film 52 is made of, for example, tantalum oxide (Ta₂O₅), in the same manner as the inner load film 51. The distance W4 between the inner load film 51 and the outer load film 52 is, for example, about 0.6 μm. The film thickness of the outer load film 52 is, for example, about 55 nm, which is the same or substantially the same as the film thickness t5 of the inner load film 51.

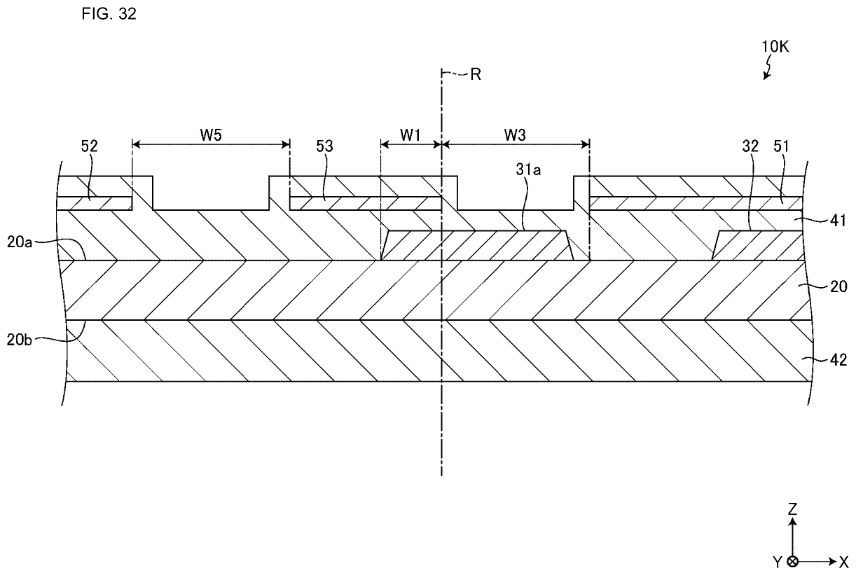

FIG. 32 is a cross-sectional view of an acoustic wave device according to a twelfth example embodiment of the present invention. As illustrated in FIG. 32, in an acoustic wave device 10K according to the twelfth example embodiment, the load film 50 is spaced apart from the multiple electrode fingers 31 and 32 and the first main surface 20a.

The load film 50 is disposed in the first protection film 41. More specifically, the first protection film 41 is disposed between the first main surface 20a of the piezoelectric layer 20 and the multiple electrode fingers 31 and 32 and the load film 50, and covers the side surfaces and the upper surface (a surface facing away from the piezoelectric layer 20) of the load film 50. In the example in FIG. 32, the upper surface of the first protection film 41 has unevenness reflecting the shape of the load film 50. In the present example embodiment, the load film 50 is not disposed over the second main surface 20b of the piezoelectric layer 20, and the lower surface of the second protection film 42 is flat. The load film 50 includes an inner load film 51, an outer load film 52, and a superposing load film 53.

As in the case of the first example embodiment, the inner load film 51 is made of, for example, tantalum oxide (Ta₂O₅). The width W1 of the superposing region of the inner load film 51 is, for example, about 0.3 μm. The film thickness of the inner load film 51, and the structures of, for example, the first protection film 41, the second protection film 42, and the IDT electrode 30 are the same or substantially the same as those in the first example embodiment. The distance between the inner load film 51 and the second main surface 20b of the piezoelectric layer 20 in a direction perpendicular or substantially the perpendicular to the second main surface 20b of the piezoelectric layer 20 is, for example, about 320 nm.

The superposing load film 53 is disposed in a region outward from the inner load film 51 in the arrangement direction and overlapping a portion of the first electrode finger 31a. The superposing load film 53 is disposed in the first protection film 41 at the same layer as the inner load film 51, and spaced apart from the inner load film 51. The outer load film 52 is made of, for example, tantalum oxide (Ta₂O₅), in the same manner as the inner load film 51. The width W1 of the superposing region of the superposing load film 53 is, for example, about 0.3 μm. The distance W3 between the inner load film 51 and the superposing load film 53 is, for example, about 0.6 μm. The film thickness of the superposing load film 53 is, for example, 55 nm, which is the same or substantially the same as the film thickness t4 of the inner load film 51.

The outer load film 52 is disposed in a region outward from the inner load film 51 and the superposing load film 53 in the arrangement direction and not overlapping the IDT electrode 30 (electrode fingers 31 and 32). The outer load film 52 is disposed in the first protection film 41 at the same layer as the inner load film 51, and spaced apart from the superposing load film 53. The outer load film 52 is made of, for example, tantalum oxide (Ta₂O₅), in the same manner as the inner load film 51. The distance W5 between the inner load film 51 and the outer load film 52 is, for example, about 0.6 μm. The film thickness of the outer load film 52 is, for example, about 55 nm, which is the same or substantially the same as the film thickness t4 of the inner load film 51.

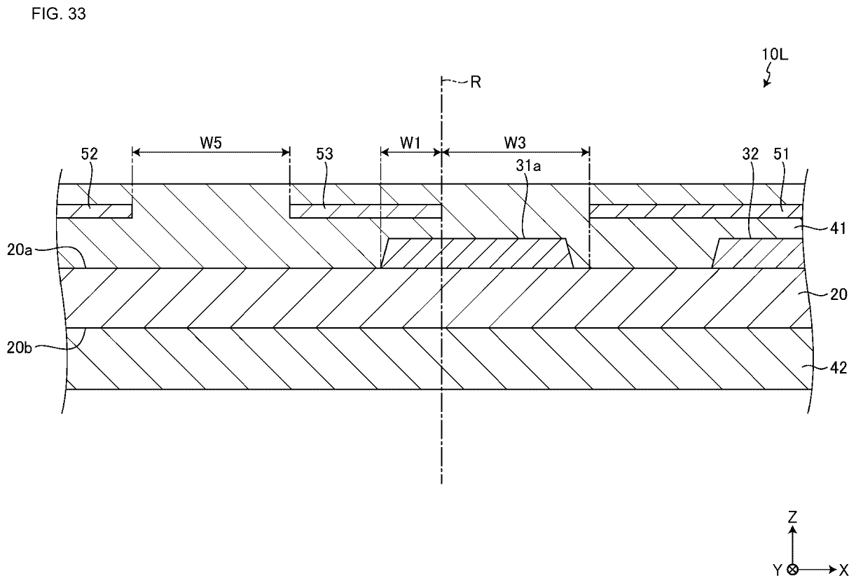

FIG. 33 is a cross-sectional view of an acoustic wave device according to a third modified example of a twelfth example embodiment of the present invention. As illustrated in FIG. 33, in an acoustic wave device 10L according to the twelfth example embodiment, the load film 50 is spaced apart from the multiple electrode fingers 31 and 32 and the first main surface 20a.

The load film 50 is disposed in the first protection film 41. More specifically, the first protection film 41 is disposed between the first main surface 20a of the piezoelectric layer 20 and the multiple electrode fingers 31 and 32 and the load film 50, and covers the side surfaces and the upper surface (a surface facing away from the piezoelectric layer 20) of the load film 50. In the example illustrated in FIG. 33, the upper surface of the first protection film 41 is flat. More specifically, the upper surface of the first protection film 41 is coplanar or substantially coplanar over the region where the load film 50 is disposed and the region where the load film 50 is not disposed. In the present example embodiment, the load film 50 is not disposed over the second main surface 20b of the piezoelectric layer 20, and the lower surface of the second protection film 42 is flat. The load film 50 includes an inner load film 51, an outer load film 52, and a superposing load film 53.

As in the case of the first example embodiment, the inner load film 51 is made of, for example, tantalum oxide (Ta₂O₅). The width W1 of the superposing region of the inner load film 51 is, for example, about 0.3 μm. The film thickness of the inner load film 51, and the structures of, for example, the first protection film 41, the second protection film 42, and the IDT electrode 30 are the same or substantially the same as those in the first example embodiment. The distance between the inner load film 51 and the second main surface 20b of the piezoelectric layer 20 in a direction perpendicular or substantially perpendicular to the second main surface 20b of the piezoelectric layer 20 is, for example, about 320 nm.

In the acoustic wave device 10L according to the third modified example of the twelfth example embodiment, the superposing load film 53 is disposed in a region outward from the inner load film 51 in the arrangement direction, and overlapping a portion of the first electrode finger 31a. The superposing load film 53 is disposed in the first protection film 41 at the same layer as the inner load film 51, and spaced apart from the inner load film 51. The superposing load film 53 is made of, for example, tantalum oxide (Ta₂O₅), in the same manner as the inner load film 51. The width W1 of the superposing region of the superposing load film 53 is, for example, about 0.3 μm. The distance W3 between the inner load film 51 and the superposing load film 53 is, for example, about 0.6 μm. The film thickness of the superposing load film 53 is, for example, 55 nm, which is the same or substantially the same as the film thickness t4 of the inner load film 51.

The outer load film 52 is disposed in a region outward from the inner load film 51 in the arrangement direction, and not overlapping the IDT electrode 30 (electrode fingers 31 and 32).

The outer load film 52 is disposed in the first protection film 41 at the same layer as the inner load film 51, and spaced apart from the superposing load film 53. The outer load film 52 is made of, for example, tantalum oxide (Ta₂O₅), in the same manner as the inner load film 51. The distance W5 between the inner load film 51 and the outer load film 52 is, for example, about 0.6 μm. The film thickness of the outer load film 52 is, for example, about 55 nm, which is the same or substantially the same as the film thickness t4 of the inner load film 51.

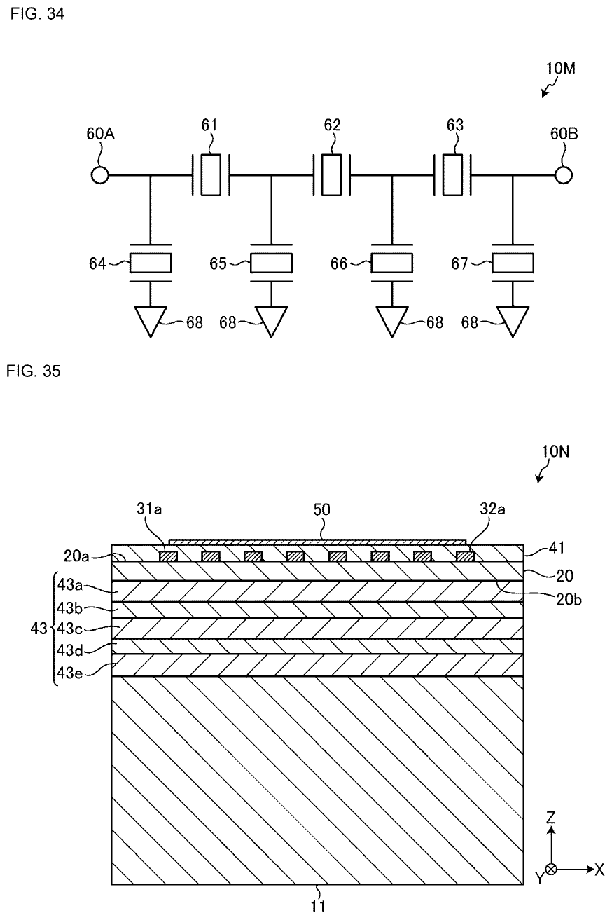

FIG. 34 is a circuit diagram of an acoustic wave filter device according to a thirteenth example embodiment of the present invention. As illustrated in FIG. 34, an acoustic wave filter device 10M according to the thirteenth example embodiment includes multiple serial arm resonators 61, 62, and 63 and multiple parallel arm resonators 64, 65, 66, and 67. The multiple serial arm resonators 61, 62, and 63 are connected in series to a signal path between an input terminal 60A and an output terminal 60B. The multiple parallel arm resonators 64, 65, 66, and 67 are connected in parallel between grounds 68 and the signal path between the input terminal 60A and the output terminal 60B. The acoustic wave filter device 10M according to the thirteenth example embodiment is a ladder filter.

The first terminals of the multiple serial arm resonators 61, 62, and 63 connected in series are electrically connected to the input terminal 60A, and the second terminals of the multiple serial arm resonators 61, 62, and 63 are electrically connected to the output terminal 60B. The first terminal of the parallel arm resonator 64 is electrically connected to the input terminal 60A, and the second terminal of the parallel arm resonator 64 is electrically connected to the corresponding ground 68. The first terminal of the parallel arm resonator 65 is electrically connected to the signal path connecting the serial arm resonator 61 and the serial arm resonator 62, and the second terminal of the parallel arm resonator 65 is electrically connected to the corresponding ground 68. The first terminal of the parallel arm resonator 66 is electrically connected to the signal path connecting the serial arm resonator 62 and the serial arm resonator 63, and the second terminal of the parallel arm resonator 66 is electrically connected to the corresponding ground 68. The first terminal of the parallel arm resonator 67 is electrically connected to the output terminal 60B, and the second terminal of the parallel arm resonator 67 is electrically connected to the corresponding ground 68.

In the present example embodiment, the multiple serial arm resonators 61, 62, and 63 each include a load film 50 with a different structure from a load film 50 included in each of the multiple parallel arm resonators 64, 65, 66, and 67. For example, the multiple serial arm resonators 61, 62, and 63 each include the load film 50 according to the first modified example (refer to FIG. 12 and FIG. 13). The admittance characteristics of the multiple serial arm resonators 61, 62, and 63 are the same as or similar to those in FIG. 15, and not described redundantly.

In contrast, the multiple parallel arm resonators 64, 65, 66, and 67 each include the load film 50 according to the second modified example (refer to FIG. 12 and FIG. 13). The admittance characteristics of the multiple parallel arm resonators 64, 65, 66, and 67 are the same as or similar to those in FIG. 14, and not described redundantly.

In the present example embodiment, the load film 50 in each of the multiple serial arm resonators 61, 62, and 63 is different from the load film 50 included in each of the multiple parallel arm resonators 64, 65, 66, and 67. Thus, the acoustic wave filter device according to the present example embodiment can define and function as a filter capable of obtaining a more preferable output wave form.

In the acoustic wave filter device 10M according to the thirteenth example embodiment described above as an example, the load film 50 according to the first modified example and the load film 50 according to the second modified example are combined, but the present invention is not limited to this example. The thirteenth example embodiment may be combined with any of the above example embodiments or modified examples.

FIG. 35 is a cross-sectional view of an acoustic wave device according to a fourteenth example embodiment of the present invention. In the acoustic wave device 10 according to the first example embodiment, a membrane structure in which the support substrate 11 includes the cavity portion 14 (hollow portion) provided on the second main surface 20b of the piezoelectric layer 20 is described, but the present invention is not limited to this example.

As illustrated in FIG. 35, in an acoustic wave device 10N according to the fourteenth example embodiment, an acoustic multilayer film 43 is laminated on the second main surface 20b of the piezoelectric layer 20. The acoustic multilayer film 43 has a multilayer structure including low acoustic impedance layers 43a, 43c, and 43e, having relatively low acoustic impedance, and high acoustic impedance layers 43b and 43d having relatively high acoustic impedance. The low acoustic impedance layers 43a, 43c, and 43e are, for example, SiO₂ layers, and the high acoustic impedance layers 43b and 43d are, for example, metal layers including, for example, W or Pt or dielectric layers made of aluminum nitride or silicon nitride. The acoustic wave device 10N including the acoustic multilayer film 43 can confine bulk waves in the thickness-shear primary mode in the piezoelectric layer 20 without including the cavity portion 14.

The acoustic wave device 10N in which d/p is, for example, less than or equal to about 0.5 is capable of obtaining resonance characteristics based on bulk waves in the thickness-shear primary mode. The number of low acoustic impedance layers 43a, 43c, and 43e and the high acoustic impedance layers 43b and 43d laminated in the acoustic multilayer film 43 is not limited to a particular one. The acoustic multilayer film 43 may include any number of impedance layers as long as at least one of the high acoustic impedance layers 43b and 43d is located further from the piezoelectric layer 20 than the low acoustic impedance layers 43a, 43c, and 43e.

The low acoustic impedance layers 43a, 43c, and 43e and the high acoustic impedance layers 43b and 43d may be made of any appropriate material that satisfies the above relationship of acoustic impedance. Examples of the material of the low acoustic impedance layers 43a, 43c, and 43e include silicon oxide or silicon oxynitride. Examples of the material of the high acoustic impedance layers 43b and 43d include alumina, silicon nitride, or metal.

FIG. 35 illustrates an example including the load film 50 according to the first example embodiment, but the present invention is not limited to this example. The fourteenth example embodiment may be combined with any of the above example embodiments or modified examples.

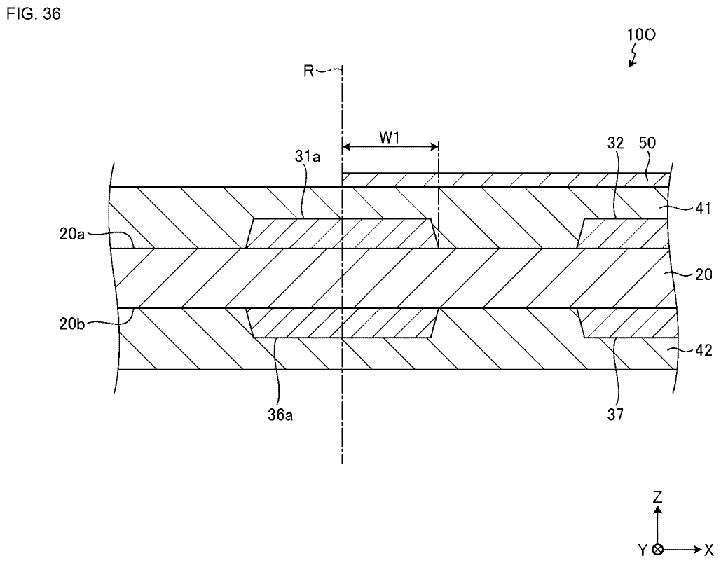

FIG. 36 is a cross-sectional view of an acoustic wave device according to a fifteenth example embodiment of the present invention. In the acoustic wave device 10 according to the first example embodiment, the IDT electrode 30 is disposed at the first main surface 20a of the piezoelectric layer 20, but the present invention is not limited to this structure. As illustrated in FIG. 36, an acoustic wave device 100 according to the fifteenth example embodiment includes a first IDT electrode disposed at the first main surface 20a of the piezoelectric layer 20 and a second IDT electrode disposed at the second main surface 20b of the piezoelectric layer 20. The first IDT electrode and the second IDT electrode have the same or substantially the same structure as the IDT electrode 30 (refer to FIGS. 1 and 2).

Electrode fingers 36 and 37 of the second IDT electrode are disposed in a region overlapping the electrode fingers 31 and 32 of the first IDT electrode. The electrode fingers 36 and 37 of the second IDT electrode have the same or substantially the same width and are arranged at the same or substantially the same inter-electrode pitch as the electrode fingers 31 and 32 of the first IDT electrode. The load film 50 is disposed in a region overlapping the first electrode finger 31a of the first IDT electrode and a first electrode finger 36a of the second IDT electrode.

In the acoustic wave device according to the fifteenth example embodiment, the first IDT electrode and the second IDT electrode are disposed on the first main surface 20a and the second main surface 20b of the piezoelectric layer 20. Thus, the acoustic wave device can improve the temperature coefficients of frequency (TCF).

FIG. 36 illustrates an example including the load film 50 according to the first example embodiment, but the invention is not limited to this example. The fifteenth example embodiment may be combined with any of the above example embodiments or modified examples.

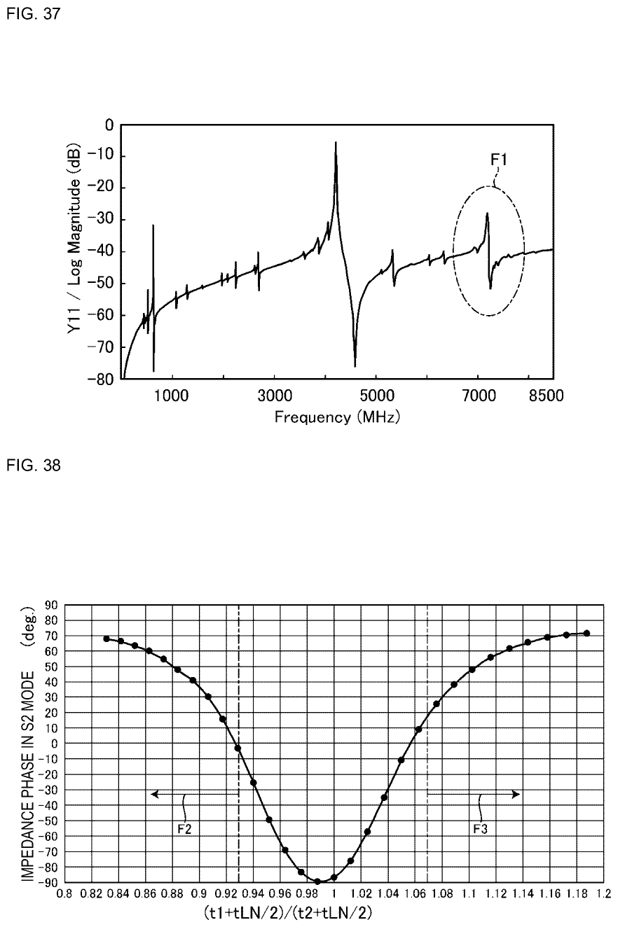

FIG. 37 is a graph of an example of admittance characteristics of an acoustic wave device according to a sixteenth example embodiment of the present invention. FIG. 38 is a graph of an example of an impedance phase in a higher mode. An acoustic wave device according to the sixteenth example embodiment illustrated in FIG. 37 differs from the acoustic wave device 10 according to the first example embodiment in that the first protection film 41 and the second protection film 42 have different film thicknesses.

FIG. 37 illustrates frequency characteristics of the absolute value of admittance of the acoustic wave device according to the sixteenth example embodiment. As illustrated in FIG. 37, in the acoustic wave device according to the sixteenth example embodiment, resonance in a higher mode occurs in the frequency range indicated by dot-and-dash line F1, different from the resonant frequency (hereafter referred to as an S2 mode).

The horizontal axis in the graph in FIG. 38 indicates the ratio ((t1+tLN/2)/(t2+tLN/2)) between the sum (t1+tLN/2) of the film thickness t1 of the first protection film 41 and one half of the film thickness tLN of the piezoelectric layer 20, and the sum (t2+tLN/2) of the film thickness t2 of the second protection film 42 and one half of the film thickness tLN of the piezoelectric layer 20. The horizontal axis of the graph in FIG. 38 corresponds to the intensity in the S2 mode.

In FIG. 38, the range indicated by arrows F2 and F3 indicates the ratio (t1+tLN/2)/(t2+tLN/2) in the structure of the acoustic resonance device described in Japanese Unexamined Patent Application Publication No. 2022-524136. In the acoustic resonance device described in Japanese Unexamined Patent Application Publication No. 2022-524136, the ratio (t1+tLN/2)/(t2+tLN/2) is less than or equal to 0.93 and greater than or equal to 1.07, and the intensity of the S2 mode is high.

In contrast, in the sixteenth example embodiment, the ratio (t1+tLN/2)/(t2+tLN/2) is, for example, within the range greater than or equal to about 0.94 and less than or equal to about 1.06, and the intensity in the S2 mode is smaller as compared with the acoustic resonance device described in Japanese Unexamined Patent Application Publication No. 2022-524136. In other words, for example, in the sixteenth example embodiment, preferably, A/B is greater than or equal to about 1−0.06 and less than or equal to about 1+0.06, where the total distance from the center of the film thickness of the piezoelectric layer 20 to the top surface of the first protection film 41 is denoted by A, and the total distance from the center of the film thickness of the piezoelectric layer 20 to the top surface of the second protection film 42 is denoted by B.

In the sixteenth example embodiment described above, as compared with the acoustic wave device 10 according to the first example embodiment, the first protection film 41 and the second protection film 42 have different film thicknesses, but the present invention is not limited to this structure. The relationship between the film thickness t1 of the first protection film 41, the film thickness tLN of the piezoelectric layer 20, and the film thickness t2 of the second protection film 42 in the sixteenth example embodiment may be combined with that in any of the example embodiments and the modified examples.

For example, the shape, the width, and the film thickness of the load film 50, the first protection film 41, the second protection film 42, and the IDT electrode 30 in each of the example embodiments and the modified examples are mere examples, and may be changed as appropriate. For example, the side surfaces of the load film 50, the first protection film 41, and the second protection film 42 may be tapered. The outer load film 52 and the superposing load film 53 overlapping the first electrode finger 31a and the second electrode finger 32a may have the same or substantially the same width and the same or substantially the same film thickness. Alternatively, the outer load film 52 and the superposing load film 53 overlapping the first electrode finger 31a and the second electrode finger 32a may have different widths and different film thicknesses due to, for example, variations caused during manufacturing processes, or may have a film thickness different from the inner load film 51. Alternatively, the first protection film 41 and the second protection film 42 may be eliminated.

The load film 50 according to each of the example embodiments and the modified examples is a mere example, and may be changed as appropriate. The load film 50 may be located in a region not overlapping the two electrode fingers (the first electrode finger 31a and the electrode finger 32) or the three electrode fingers (the first electrode finger 31a, the electrode finger 32, and the electrode finger 31) located outward in the arrangement direction.

The material of the load film 50 according to each of the example embodiments and the modified examples is a mere example, and may be changed as appropriate. The load film 50 is made of a material including, for example, at least one of carbon-doped silicon oxide (SiOC), silicon oxide (SiO₂), silicon nitride (SiN), tantalum oxide (Ta₂O₅), aluminum nitride (AlN), aluminum oxide (Al₂O₃), hafnium oxide (HfO₂), niobium oxide (Nb₂O₅), or tungsten oxide (WO). The load film 50 may be a multilayer film instead of a single-layer film. The load film 50 may be made of two or more of the above materials, for example.

The above-described example embodiments are provided merely to facilitate understanding of the present invention, and are not intended to limit the present invention. The present invention may be modified or altered without departing from the scope and spirit of the present invention, and also encompasses equivalents thereof.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a piezoelectric layer including a first main surface and a second main surface opposite to the first main surface in a first direction;
an interdigital transducer (IDT) electrode on at least one of the first main surface or the second main surface of the piezoelectric layer, and including a plurality of electrode fingers arranged in an arrangement direction;
a support facing the second main surface of the piezoelectric layer, and including an acoustic reflection portion at a portion closer to the second main surface of the piezoelectric layer; and
a load film extending over a region that overlaps, when viewed in plan in the first direction, at least electrode fingers from a fourth electrode finger of the plurality of electrode fingers from a first outer end in the arrangement direction to a fourth electrode finger of the plurality of electrode fingers from a second outer end in the arrangement direction; wherein
the load film is not located over at least a portion of a region that overlaps, in a plan view, a first electrode finger of the plurality of electrode fingers located outermost in the arrangement direction; and
d/p is less than or equal to about 0.5, where d denotes a thickness of the piezoelectric layer, and p denotes a center-to-center distance between adjacent two of the electrode fingers.

2. The acoustic wave device according to claim 1, further comprising a protection film on least one of the first main surface or the second main surface of the piezoelectric layer.

3. The acoustic wave device according to claim 1, further comprising:
a protection film on at least one of the first main surface or the second main surface of the piezoelectric layer; wherein
the protection film includes a first protection film on the first main surface of the piezoelectric layer while covering the IDT electrode; and
the load film is on the first protection film.

4. The acoustic wave device according to claim 1, wherein the load film is located at a portion not overlapping an outer portion of the IDT electrode in the arrangement direction.

5. The acoustic wave device according to claim 1, further comprising:
a protection film on at least one of the first main surface or the second main surface of the piezoelectric layer; wherein
the protection film includes a first protection film on the first main surface of the piezoelectric layer while covering the IDT electrode and a second protection film at the second main surface of the piezoelectric layer; and
the load film is located at a surface of the second protection film facing the support.

6. The acoustic wave device according to claim 1, further comprising:
a protection film on at least one of the first main surface or the second main surface of the piezoelectric layer; wherein
the protection film includes a first protection film on the first main surface of the piezoelectric layer while covering the IDT electrode and a second protection film on the second main surface of the piezoelectric layer; and
the load film includes an upper load film on the first protection film and a lower load film on a surface of the second protection film facing the support.

7. The acoustic wave device according to claim 1, further comprising:
a protection film on at least one of the first main surface or the second main surface of the piezoelectric layer; wherein
the protection film includes a first protection film on the first main surface of the piezoelectric layer while covering the IDT electrode;
the load film is on the first protection film; and
in a region overlapping the first electrode finger, a level difference is provided by a portion in which the first protection film is provided and the load film is not provided and a portion in which the load film and the first protection film are laminated.

8. The acoustic wave device according to claim 1, further comprising:
a protection film on at least one of the first main surface or the second main surface of the piezoelectric layer; wherein
the protection film includes a first protection film on the first main surface of the piezoelectric layer while covering the IDT electrode; and
the load film is provided in the first protection film.

9. The acoustic wave device according to claim 8, wherein
the protection film includes a first protection film on the first main surface of the piezoelectric layer while covering the IDT electrode; and
in a region overlapping the first electrode finger, a level difference is provided by a portion in which the first protection film is provided and the load film is not provided and a portion in which the load film and the first protection film are laminated.

10. The acoustic wave device according to claim 8, wherein
the protection film includes a first protection film on the first main surface of the piezoelectric layer while covering the IDT electrode and a second protection film on the second main surface of the piezoelectric layer; and
the load film is provided in the second protection film.

11. The acoustic wave device according to claim 8, wherein
the protection film includes a first protection film on the first main surface of the piezoelectric layer while covering the IDT electrode and a second protection film on the second main surface of the piezoelectric layer; and
the load film includes an upper load film provided in the first protection film and a lower load film provided in the second protection film.

12. The acoustic wave device according to claim 8, wherein
the protection film includes a first protection film on the first main surface of the piezoelectric layer while covering the IDT electrode and a second protection film on the second main surface of the piezoelectric layer; and
an upper surface of the first protection film and a lower surface of the second protection film are flat.

13. The acoustic wave device according to claim 8, wherein the load film is on the first electrode finger.

14. The acoustic wave device according to claim 8, wherein the load film is between the first main surface of the piezoelectric layer and the first electrode finger in a direction perpendicular or substantially perpendicular to the first main surface of the piezoelectric layer.

15. The acoustic wave device according to claim 8, wherein
the protection film includes a first protection film on the first main surface of the piezoelectric layer and covering the IDT electrode and a second protection film on the second main surface of the piezoelectric layer;
the load film is provided at the second main surface of the piezoelectric layer; and
the second protection film covers the load film.

16. The acoustic wave device according to claim 1, further comprising:
a protection film on at least one of the first main surface or the second main surface of the piezoelectric layer; wherein
the load film includes a material with a higher density than the protection film.

17. The acoustic wave device according to claim 1, further comprising:
a protection film on at least one of the first main surface or the second main surface of the piezoelectric layer; wherein
the load film includes a material with a lower density than the protection film.

18. The acoustic wave device according to claim 1, further comprising:
a protection film on at least one of the first main surface or the second main surface of the piezoelectric layer; wherein
the load film includes a material with greater hardness than the protection film.

19. The acoustic wave device according to claim 1, further comprising:
a protection film on at least one of the first main surface or the second main surface of the piezoelectric layer; wherein
the protection film includes silicon oxide.

20. The acoustic wave device according to claim 1, further comprising:
a protection film on at least one of the first main surface or the second main surface of the piezoelectric layer; wherein
a film thickness of the protection film is less than a film thickness of the piezoelectric layer.

21. An acoustic wave filter device, comprising:
at least one resonator including the acoustic wave device according to claim 1.

22. The acoustic wave filter device according to claim 21, further comprising:
an input terminal;
an output terminal;
a serial arm connecting the input terminal and the output terminal; and
a parallel arm connecting a ground and a node of the serial arm; wherein
the at least one resonator includes a plurality of resonators including a serial arm resonator at the serial arm and a parallel arm resonator at the parallel arm;
each of the serial arm resonator and the parallel arm resonator includes the load film; and
the load film of the serial arm resonator has a different structure from the load film of the parallel arm resonator.

23. The acoustic wave filter device according to claim 21, further comprising:
an input terminal;
an output terminal;
a serial arm connecting the input terminal and the output terminal; and
a parallel arm connecting a ground and a node of the serial arm; wherein
the at least one resonator includes a plurality of resonators including a serial arm resonator at the serial arm and a parallel arm resonator at the parallel arm;
each of the serial arm resonator and the parallel arm resonator includes the load film; and
the load film of the serial arm resonator has a different thickness from the load film of the parallel arm resonator.

24. The acoustic wave device according to claim 1, wherein the piezoelectric layer includes lithium niobate or lithium tantalate, and has a cut-angle of a rotated Y-cut of about 120°±10° or about 90°±10°.

25. The acoustic wave device according to claim 1, further comprising:
a protection film on at least one of the first main surface or the second main surface of the piezoelectric layer; wherein
the protection film includes a first protection film on the first main surface of the piezoelectric layer and covering the IDT electrode and a second protection film on the second main surface of the piezoelectric layer.

26. The acoustic wave device according to claim 1, further comprising:
a protection film on at least one of the first main surface or the second main surface of the piezoelectric layer; wherein
a film thickness of the protection film is greater than a film thickness of the IDT electrode.

27. The acoustic wave device according to claim 1, further comprising:
a protection film on at least one of the first main surface or the second main surface of the piezoelectric layer; wherein
the protection film includes a first protection film on the first main surface of the piezoelectric layer and covering the IDT electrode and a second protection film on the second main surface of the piezoelectric layer; and
A/B is greater than or equal to about 1−0.06 and less than or equal to about 1+0.06, where A denotes a total distance from a center of a film thickness of the piezoelectric layer to a top surface of the first protection film, and B denotes a total distance from a center of the film thickness of the piezoelectric layer to a top surface of the second protection film.

28. The acoustic wave device according to claim 1, wherein the IDT electrode is on each of the first main surface and the second main surface of the piezoelectric layer.

29. The acoustic wave device according to claim 1, wherein a material of the load film includes at least one of carbon-doped silicon oxide, silicon oxide, silicon nitride, tantalum oxide, aluminum nitride, aluminum oxide, hafnium oxide, niobium oxide, or tungsten oxide.

30. The acoustic wave device according to claim 1, wherein d/p is less than or equal to about 0.24.

31. The acoustic wave device according to claim 1, wherein MR≤about 1.75 (d/p)+0.075 is satisfied, where MR denotes a metallization ratio of any adjacent two of the electrode fingers of the plurality of electrode fingers to an excitation region that is a region in which the adjacent two of the electrode fingers overlap when viewed in a direction perpendicular or substantially perpendicular to the electrode fingers and that is a region between centers of the adjacent two of the electrode fingers in a direction perpendicular to the electrode fingers.

32. The acoustic wave device according to claim 1,
wherein the piezoelectric layer includes lithium tantalate or lithium niobate.

33. The acoustic wave device according to claim 32, wherein
Euler angles (0°, θ, ψ) of lithium niobate or lithium tantalate included in the piezoelectric layer are within ranges of Formula (1), Formula (2), or Formula (3):
$$( 0 ° \pm 10 ° , 0 ° to 20 ° , any ψ ) ; \qquad Formula ( 1 )$$
$$( 0 ° \pm 10 ° , 20 ° to 80 ° , 0 ° to 60 ° {( 1 - {( θ - 50 )}^{2} / 900 )}^{1 / 2} ) or ( 0 ° \pm 10 ° , 20 ° to 80 ° , \{ 180 ° - 60 ° {( 1 - {( θ - 50 )}^{2} / 900 )}^{1 / 2} \} to 180 ° ) ; or \qquad Formula ( 2 )$$
$$Formula ( 3 )$$
$$( 0 ° \pm 10 ° , \{ 180 ° - 30 ° {( 1 - {( ψ - 90 )}^{2} / 8100 )}^{1 / 2} \} to 180 ° , any ψ ) .$$

34. The acoustic wave device according to claim 1, wherein
the acoustic reflection portion includes a hollow portion; and
a portion of the support and a portion of the piezoelectric layer face each other across the hollow portion.

35. The acoustic wave device according to claim 1, wherein
the acoustic reflection portion includes an acoustic reflection film including a high acoustic impedance layer with a relatively high acoustic impedance and a low acoustic impedance layer with a relatively low acoustic impedance; and
at least a portion of the support and at least a portion of the piezoelectric layer face each other with the acoustic reflection film interposed therebetween.
